(19) United States
(12) Patent Application Publication
(10) Pub. No.: US 2025/0120200 A1
(43) Pub. Date: Apr. 10, 2025

(54) IMAGE SENSOR

(71) Applicant: Samsung Electronics Co., Ltd., Suwon-si (KR)

(72) Inventors: Sungyoon Min, Suwon-si (KR); JEONGJIN CHO, Suwon-si (KR); Seunghwan Lee, Suwon-si (KR); MINJI JUNG, Suwon-si (KR)

(21) Appl. No.: 18/884,591

(22) Filed: Sep. 13, 2024

(30) Foreign Application Priority Data
Oct. 10, 2023 (KR) 10-2023-0134569

(51) Int. Cl. H01L 27/146

(52) U.S. Cl. CPC H10F 39/8027; H10F 39/182; H10F 39/8063; H10F 39/807

(57) ABSTRACT

Disclosed is an image sensor including first and second pixels adjacent along a first direction, a first micro lens disposed on the first and second pixels, a first pixel isolation structure disposed outside the first and second pixels and penetrating from a first surface of a substrate to a second surface of the substrate opposite the first surface of the substrate, and a first floating diffusion region disposed at the first pixel and the second pixel and adjacent to the first surface of the substrate. The first floating diffusion region may not overlap the first pixel isolation structure along a height direction perpendicular to the first and second surfaces of the substrate, and the first floating diffusion region between the first pixel and the second pixel may be disposed at a position corresponding to a center portion of the first micro lens along an optical axis direction.

### CROSS-REFERENCE TO RELATED APPLICATION

This application claims priority under 35 U.S.C. § 119 to and the benefit of Korean Patent Application No. 10-2023-0134569, filed in the Korean Intellectual Property Office on Oct. 10, 2023, the entire contents of which are incorporated herein by reference.

### BACKGROUND

### (a) Field

The present disclosure relates to an image sensor.

### (b) Description of the Related Art

Complementary metal-oxide semiconductor (CMOS) image sensors are solid-state imaging devices that use complementary metal-oxide semiconductors. CMOS image sensor have lower manufacturing costs compared to charge-coupled device (CCD) image sensors. In addition, CMOS image sensors have smaller size compared to CCD image sensors having a high-voltage analog circuit, and thus, consume less power. As a result, CMOS image sensors are frequently used for electronic appliances including portable devices such as smartphones and digital cameras.

A pixel array included in a CMOS image sensor includes a photoelectric conversion element in each pixel. The photoelectric conversion element may generate an electrical signal that varies based on the quantity of incident light. The CMOS image sensor may process the electrical signal to synthesize an image.

Recently, in response to the demand for high-resolution images, many efforts have been made to reduce image noise in low-light conditions. For example, it is possible to obtain images in low-light conditions using a plurality of pixels.

However, when an image is obtained using a plurality of pixels, the readout speed for the plurality of pixels may be slow and the frame rate may decrease. Additionally, when an image is obtained using a relatively large number of pixels, image quality may deteriorate when remosaicing an image of a plurality of pixels in high-light conditions.

### SUMMARY

Embodiments provide an image sensor capable of preventing frame rate deterioration and remosaic image quality deterioration while obtaining an image using a plurality of pixels.

However, embodiments of the present disclosure are not limited to those mentioned above, and may be variously extended in the scope of the technical ideas included in the present disclosure.

An image sensor according to an embodiment may comprise a first pixel and a second pixel adjacent to each other along a first direction; a first micro lens disposed on the first pixel and the second pixel; a first pixel isolation structure disposed outside the first pixel and the second pixel and penetrating from a first surface of a substrate to a second surface of the substrate opposite the first surface of the substrate; a first floating diffusion region disposed at the first pixel and the second pixel and adjacent to the first surface of the substrate; a first transfer gate disposed at the first pixel and adjacent to the first floating diffusion region; a second transfer gate disposed at the second pixel and adjacent to the first floating diffusion region; a first active region disposed at the first pixel and adjacent to the first surface of the substrate; a first gate disposed at the first pixel and overlapping the first active region; a second active region disposed at the second pixel and adjacent to the first surface of the substrate; and a second gate disposed at the second pixel and overlapping the second active region. The first floating diffusion region does not overlap the first pixel isolation structure along a height direction perpendicular to the first and second surfaces of the substrate, and the first floating diffusion region between the first pixel and the second pixel may be disposed at a position corresponding to a center portion of the first micro lens along an optical axis direction.

According to embodiments, it is possible to provide an image sensor capable of preventing frame rate deterioration and remosaic image quality deterioration while obtaining an image using a plurality of pixels.

However, embodiments of the present disclosure are not limited to those mentioned above, and may be variously extended in the scope of the technical ideas included in the present disclosure.

### BRIEF DESCRIPTION OF THE DRAWINGS

FIG. 1 is a block diagram schematically illustrating an image sensor according to an example embodiment.

FIG. 2 is a top plan view illustrating a part of an image sensor according to an example embodiment.

FIG. 3 is a circuit diagram of a pixel group of an image sensor according to an example embodiment.

FIG. 4 is an enlarged view of a part of FIG. 2.

FIG. 5 is a cross-sectional view taken along I-I′ line of FIG. 4.

FIG. 6 is a cross-sectional view taken along II-Il' line of FIG. 4.

FIGS. 7 and 8 are diagrams illustrating the optical axis direction of an image sensor according to an example embodiment.

FIG. 9 is a top plan view illustrating a pixel group of an image sensor according to another example embodiment.

FIG. 10 is a cross-sectional view taken along I-I′ line of FIG. 9.

FIG. 11 is a top plan view illustrating a pixel group of an image sensor according to another example embodiment.

FIG. 12 is a top plan view illustrating a pixel group of an image sensor according to another example embodiment.

FIG. 13 is a top plan view illustrating a pixel group of an image sensor according to another example embodiment.

FIG. 14 is a top plan view illustrating a pixel group of an image sensor according to another example embodiment.

FIG. 15 is a top plan view illustrating a pixel group of an image sensor according to another example embodiment.

FIG. 16 is a top plan view illustrating a part of an image sensor according to another example embodiment.

FIG. 17 is a top plan view illustrating a part of an image sensor according to an example embodiment.

FIG. 18 is a top plan view illustrating a part of an image sensor according to another example embodiment.

FIG. 19 is a top plan view illustrating a part of an image sensor according to an example embodiment.

FIG. 20 is a circuit diagram of a pixel group of an image sensor according to an example embodiment.

FIG. 21 is an enlarged view of a part of FIG. 20.

FIG. 22 is a top plan view illustrating a part of an image sensor according to another example embodiment.

FIG. 23 is a top plan view illustrating a part of an image sensor according to another example embodiment.

FIG. 24 is a top plan view illustrating a part of an image sensor according to another example embodiment.

### DETAILED DESCRIPTION OF THE EMBODIMENTS

The present disclosure will be described in detail hereinafter with reference to the accompanying drawings, in which embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

In addition, the accompanying drawings are intended only to facilitate an understanding of the embodiments disclosed in this specification, and it is to be understood that the technical ideas disclosed herein are not limited by the accompanying drawings and include all modifications, equivalents, or substitutions that are within the range of the ideas and technology of the present disclosure.

Size and thickness of each constituent element in the drawings are arbitrarily illustrated for better understanding and ease of description, the following embodiments are not limited thereto. In the drawings, the thickness of layers, films, panels, regions, etc., are exaggerated for clarity. In the drawings, the thickness of some layers and regions may be exaggerated for ease of description.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “on” or “above” a reference element, it can be positioned above or below the reference element, and it is not necessarily referred to as being positioned “on” or “above” in a direction opposite to gravity.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Throughout the specification, the term “connected” does not mean only that two or more constituent components are directly connected, but may also mean that two or more constituent components are indirectly connected through another constituent component, that two or more components are electrically connected as well as physically connected, or that two or more constituent components are referred to by different names but are united by location or function. The term “contact,” as used herein, refers to a direct connection (i.e., touching) unless the context indicates otherwise.

Hereinafter, various embodiments and variations will be described in detail with reference to the drawings.

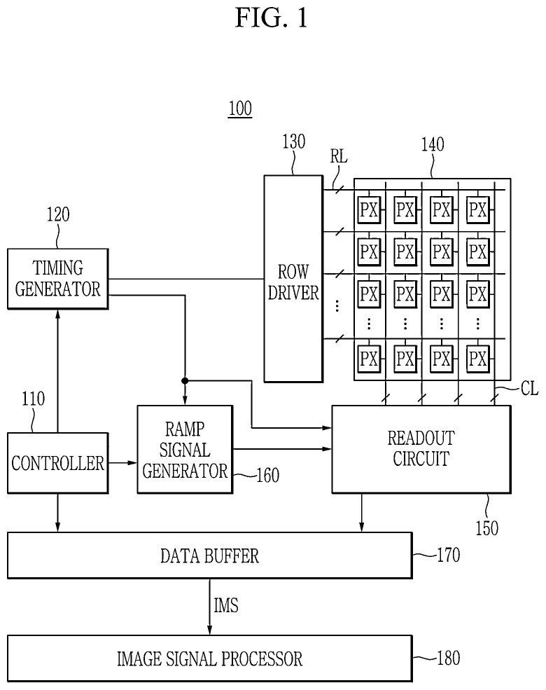

Referring to FIG. 1, an image sensor according to an embodiment will be briefly described. FIG. 1 is a block diagram schematically illustrating an image sensor according to an example embodiment.

Referring to FIG. 1, an image sensor 100 according to an embodiment may include a pixel array 140 and a logic circuit that controls the pixel array 140.

The logic circuit is a circuit for controlling the pixel array 140, and may include, for example, a controller 110, a timing generator 120, a row driver 130, a readout circuit 150, a ramp signal generator 160, and a data buffer 170, and the like.

Additionally, the image sensor 100 may further include an image signal processor 180. In some embodiments, the image signal processor 180 may be disposed outside the image sensor 100. The image sensor 100 may generate an image signal by converting light received from the outside into an electrical signal. The image signal generated by the image sensor 100 may be provided to the image signal processor 180.

The image sensor 100 may be mounted on an electronic device having an image or light sensing function. For example, the image sensor 100 may be mounted on electronic devices such as cameras, smartphones, wearable devices, internet of things (IoT) devices, home appliances, tablet PCs (Personal Computers), navigation, drones, advanced driver assistance systems (ADAS), etc. Additionally, the image sensor 100 may be mounted on electronic devices that are included as components in vehicles, furniture, manufacturing facilities, doors, and various measuring devices.

The pixel array 140 may include a plurality of pixels PX, a plurality of row lines RL respectively connected to the plurality of pixels PX, and a plurality of column lines CL respectively connected to the plurality of pixels PX.

In an embodiment, each pixel PX may include at least one photoelectric conversion element. A photoelectric conversion element may detect incident light and convert the incident light into an electrical signal according to the amount of light, that is, a plurality of analog pixel signals. For example, each of the photoelectric conversion elements may output an analog pixel signal corresponding to the amount of incident light detected by the photoelectric conversion element.

The photoelectric conversion element may be a photodiode, a pinned diode, or the like. Additionally, the photoelectric conversion element may be a single-photon avalanche diode SPAD applied to a 3D sensor pixel.

The level of the analog pixel signal output from the photoelectric conversion element may be proportional to the amount of charge output from the photoelectric conversion element. For example, the level of the analog pixel signal output from the photoelectric conversion element may be determined depending on the amount of light received into the pixel array 140.

The plurality of row lines RL may be connected to the plurality of pixels PX. For example, a control signal output from the row driver 130 to one row line RL of the plurality of row lines RL may be transmitted to the gates of transistors of the plurality of pixels PX connected to the one row line RL. The column lines CL are arranged to intersect the row lines RL and may be connected to the plurality of pixels PX. For example, each row line RL may be connected to a plurality of column lines CL, and each column line CL may be connected to a plurality of row lines RL. A plurality of pixel signals output from the plurality of pixels PX may be transmitted to the readout circuit 150 through the plurality of column lines CL.

In an embodiment, the plurality of pixels PX may be grouped in the form of a plurality of columns and a plurality of rows to form one unit pixel group. For example, the plurality of pixels PX arranged in the arrangement direction of the column lines CL and the plurality of pixels PX arranged in the arrangement direction of the row lines RL may form one unit pixel group PG. For example, one unit pixel group PG may include the plurality of pixels PX arranged in two columns and/or two rows, and one unit pixel group PG may output one analog pixel signal. However, the embodiment is not limited thereto, and various modifications are possible.

The controller 110 may control the operation timing of each of the constituent elements described above—i.e., the timing generator 120, the row driver 130, the readout circuit 150, the ramp signal generator 160, and the data buffer 170—using control signals.

In an embodiment, the controller 110 may receive a mode signal indicating an imaging mode from an application processor, and generally control the image sensor 100 based on the received mode signal. For example, the application processor may determine the imaging mode of the image sensor 100 according to various scenarios such as the illumination of the imaging environment, the user's resolution setting, and the sensed or learned state, and may provide the determined result to the controller 110 as a mode signal.

The controller 110 may control the plurality of pixels PX of the pixel array 140 to output pixel signals according to the imaging mode. The pixel array 140 may output a pixel signal for each of the plurality of pixels PX and pixel signals for some of the plurality of pixels PX. The readout circuit 150 may sample and process pixel signals received from the pixel array 140.

The timing generator 120 may generate a signal that serves as a reference for the operation timing of the components of the image sensor 100. The timing generator 120 may control the timing of the row driver 130, the readout circuit 150, and the ramp signal generator 160. The timing generator 120 may provide a control signal that controls the timing of the row driver 130, the readout circuit 150, and the ramp signal generator 160.

The row driver 130 may generate a control signal for driving the pixel array 140 in response to a control signal received from the timing generator 120, and provide the control signal to the plurality of pixels PX of the pixel array 140 through the plurality of row lines RL.

In an embodiment, the row driver 130 may control the pixels PX to sense incident light in row line units.

A row line unit may include at least one row line RL, and the row driver 130 may control the pixels PX connected to the at least one row line RL to sense incident light. For example, the row driver 130 may generate a transmission signal for controlling a transfer transistor, a reset control signal for controlling a reset transistor, and a selection control signal for controlling a selection transistor, and provide the generated signals (e.g., the transmission signal, the reset control signal, the selection control signal) to the pixel array 140.

The readout circuit 150 may convert a pixel signal (or electric signal) from the pixels PX connected to the row line RL selected from among the plurality of pixels PX into a pixel value representing the quantity of light in response to a control signal from the timing generator 120.

The readout circuit 150 may convert a pixel signal output through a corresponding column line CL into a pixel value. For example, the readout circuit 150 may convert a pixel signal into a pixel value by comparing the ramp signal and the pixel signal. The pixel value may be image data having a plurality of bits. Specifically, the readout circuit 150 may include a selector, a plurality of comparators, and a plurality of counter circuits.

The ramp signal generator 160 may generate a reference signal and transmit the reference signal to the readout circuit 150. The ramp signal generator 160 may include a current source, a resistor, and a capacitor. The ramp signal generator 160 may generate a plurality of ramp signals that fall or rise with a slope determined according to the current size of the variable current source or the resistance value of the variable resistor, by adjusting the ramp voltage applied to the ramp resistance by controlling the current size of the variable current source or the resistance value of the variable resistor.

The data buffer 170 may store pixel values of the plurality of pixels PX connected to the selected column line CL transmitted from the readout circuit 150, and output the stored pixel values in response to an enable signal from the controller 110.

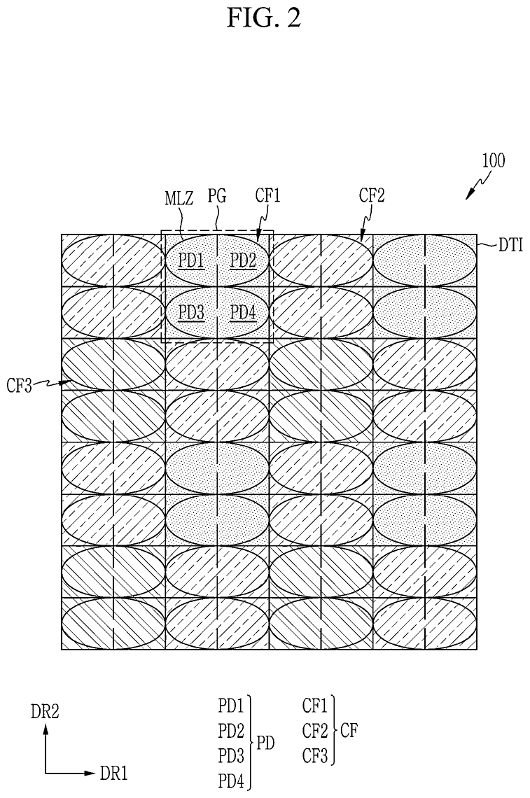

The image signal processor 180 may perform image signal processing on the image signal received from the data buffer 170. For example, the image signal processor 180 may receive a plurality of image signals from the data buffer 170, and generate one image by synthesizing the received image signals. Referring to FIG. 2, a pixel arrangement of an image sensor according to an example embodiment will be described. FIG. 2 is a plan view illustrating a part of an image sensor according to an example embodiment.

Referring to FIG. 2, the image sensor 100 according to an embodiment may include pixel groups PG, photodiodes PD, color filters CF, micro lenses MLZ, and other circuits required for operation of the image sensor 100.

The plurality of pixels PX may be grouped in a plurality of columns and a plurality of rows to form one unit pixel group PG. For example, one pixel group PG may include pixels PX from a plurality of columns and a plurality of rows.

The pixel group PG overlapping a first color filter CF1 may detect light of a first color, the pixel group PG overlapping a second color filter CF2 may detect light of a second color different from the first color, and the pixel group PG overlapping a third color filter CF3 may detect light of a third color different from the first and second colors.

Each of the plurality of pixel groups PG may include N×M pixels PX in an N×M arrangement. The N and the M may each independently be an integer greater than 1. For example, each of N and M may be 2, and may have a 2×2 tetra structure pixel arrangement in a plan view. For example, each of the plurality of pixel groups PG may include pixels PX arranged in a 2×2 shape on a plane.

More specifically, the plurality of pixels PX disposed in the arrangement direction of the column line CL and the plurality of pixels PX disposed in the arrangement direction of the row line RL may configure one unit pixel group PG. For example, one unit pixel group PG may include a plurality of pixels PX arranged in two columns and two rows. However, the embodiment is not limited thereto, and the number of pixels PX included in one pixel group PG may be variously modified.

Micro lenses MLZ may be disposed one per every two adjacent pixels PX. For example, the micro lenses MLZ may be disposed one per every two adjacent pixels PX in a first direction DR1.

The image sensor 100 according to the embodiment includes a first pixel row in which pixel groups PG corresponding to a first color filter CF1 and a second color filter CF2 are alternately arranged in the first direction DR1, and a second pixel row in which pixel groups PG corresponding to the second color filter CF2 and a third color filter CF3 are alternately arranged in the first direction DR1. The first pixel row and the second pixel row may be alternately arranged in a second direction DR2.

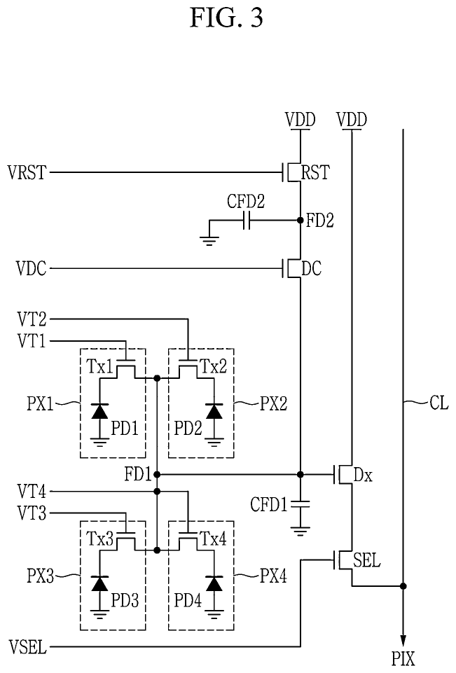

With reference to FIG. 3, the operation of one pixel group of an image sensor according to an example embodiment will be briefly described. FIG. 3 is a circuit diagram of a pixel group of an image sensor according to an example embodiment.

Referring to FIG. 3, a pixel group PG of an image sensor according to an embodiment may include pixels PX1 to PX4, photoelectric conversion elements PD1 to PD4, transfer transistors Tx1 to Tx4, a reset transistor RST, a dual conversion transistor DC, a driving transistor Dx, and a selection transistor SEL. As described above, the pixel group PG is shown as having four pixels PX1 to PX4 each including photoelectric conversion elements PD1 to PD4, but the present disclosure is not limited thereto, and the pixel group PG may be implemented to have various other structures.

The first pixel PX1 may include the first photoelectric conversion element PD1 and the first transfer transistor Tx1, the second pixel PX2 may include the second photoelectric conversion element PD2 and the second transfer transistor Tx2, the third pixel PX3 may include the third photoelectric conversion element PD3 and the third transfer transistor Tx3, and the fourth pixel PX4 may include the fourth photoelectric conversion element PD4 and the fourth transfer transistor Tx4.

The pixels PX1 to PX4 of one pixel group PG may share the reset transistor RST, the dual conversion transistor DC, the driving transistor Dx, and the selection transistor SEL. Additionally, each of the pixels PX1 to PX4 may share a first floating diffusion region FD1.

The first floating diffusion region FD1 or a second floating diffusion region FD2 may accumulate charges corresponding to the amount of incident light.

While the transfer transistors Tx1 to Tx4 are each turned on by the transfer signals VT1 to VT4, the first floating diffusion region FD1 or the second floating diffusion region FD2 may receive and accumulate charges from the photoelectric conversion elements PD1 to PD4.

Since the first floating diffusion region FD1 may be connected to the gate terminal of the driving transistor Dx driven as a source follower amplifier, a voltage corresponding to the charges accumulated in the first floating diffusion region FD1 may be formed. For example, the capacitance of the first floating diffusion region FD1 may be represented as a first capacitance CFD1.

The dual conversion transistor DC may be driven by a dual conversion signal VDC. When the dual conversion transistor DC is turned off, the capacitance of the first floating diffusion region FD1 may correspond to the first capacitance CFD1.

In a general environment, the first floating diffusion region FD1 is not easily saturated, so the need to increase the capacitance of the first capacitance CFD1 of the first floating diffusion region FD1 may not be required, and the dual conversion transistor DC may be turned off.

However, in a high-light environment, the first floating diffusion region FD1 may easily become saturated. To prevent such saturation, the dual conversion transistor DC may be turned on, the first floating diffusion region FD1 may be electrically connected to the second floating diffusion region FD2, and the capacitance of the floating diffusion regions FD1 and FD2 may be expanded to the sum of the first capacitance CFD1 and the second capacitance CFD2.

The transfer transistors Tx1 to Tx4 may each be driven by the transfer signals VT1 to VT4, and may transmit charges generated by photoelectric conversion elements PD1 to PD4 to the first floating diffusion region FD1 or the second floating diffusion region FD2. For example, one end of each of the transfer transistors Tx1 to Tx4 may be connected to the photoelectric conversion elements PD1 to PD4, respectively, and the other end of each of the transfer transistors Tx1 to Tx4 may be connected to the first floating diffusion region FD1.

The reset transistor RST may be driven by the reset signal VRST and may provide a power supply voltage VDD to the first floating diffusion region FD1 or the second floating diffusion region FD2. Accordingly, the charges accumulated in the first floating diffusion region FD1 or in the expanded second floating diffusion region FD2 may move to the power supply voltage VDD end, and the voltage of the first floating diffusion region FD1 or the second floating diffusion region FD2 may be reset.

The driving transistor Dx may generate a pixel signal PIX by amplifying the voltage of the first floating diffusion region FD1 or the second floating diffusion region FD2. The selection transistor SEL may be driven by the selection signal VSEL, and may select pixels to be read in row units. When the selection transistor SEL is turned on, the pixel signal PIX may be output to the readout circuit 150 through the column line CL.

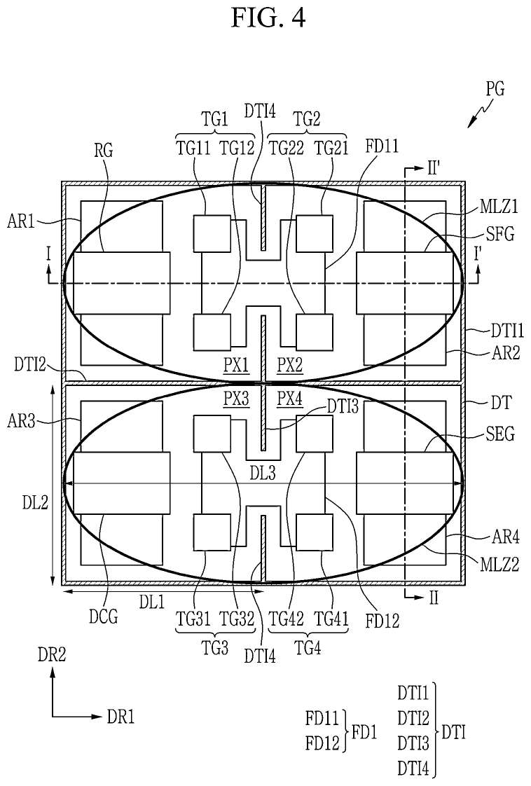

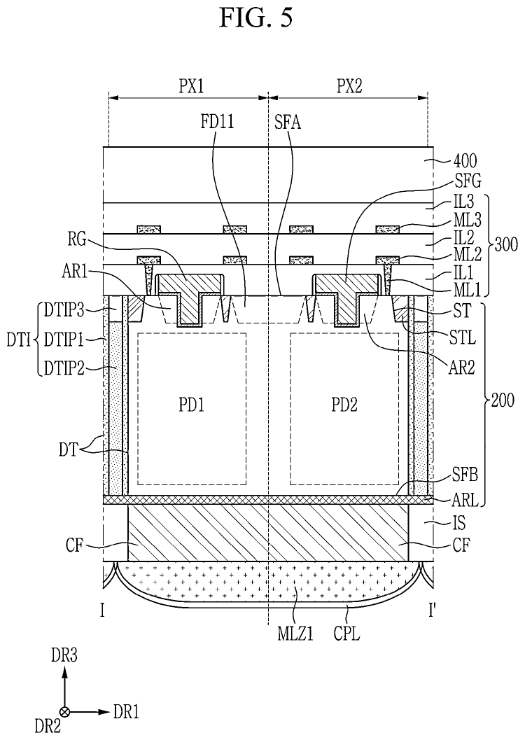

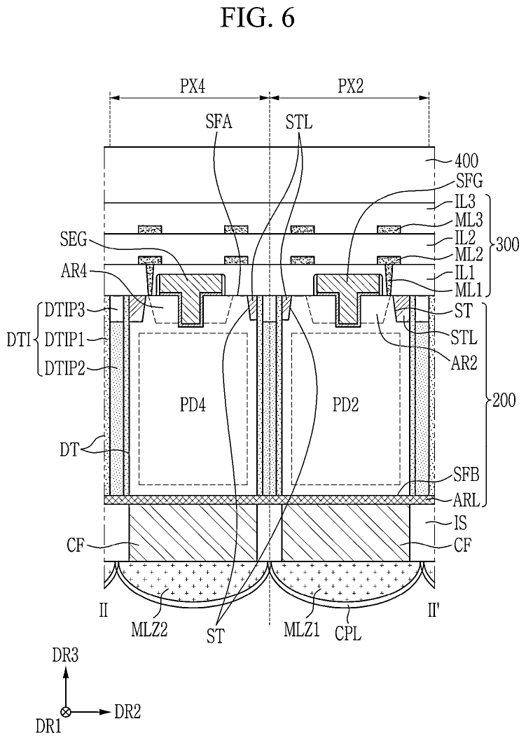

Then, with reference to FIGS. 4 to 6, the image sensor according to an example embodiment will be described in more detail. FIG. 4 is an enlarged view of a part of FIG. 2, FIG. 5 is a cross-sectional view taken along I-I′ line of FIG. 4, and FIG. 6 is a cross-sectional view taken along II-II′ line of FIG. 4.

Referring to FIG. 4, the image sensor 100 according to an embodiment may include the pixel group PG including the plurality of pixels PX1, PX2, PX3 and PX4.

The plurality of pixels PX1, PX2, PX3 and PX4 may include the first pixel PX1, the second pixel PX2, the third pixel PX3, and the fourth pixel PX4 that are adjacent to each other in the first direction DR1 and in the second direction DR2 different from the first direction DR1.

On a plane formed by different first directions DR1 and second directions DR2, the first pixel PX1 and the second pixel PX2 may be arranged adjacent to each other along the first direction DR1, and the third pixel PX3 and the fourth pixel PX4 may be arranged adjacent to each other. In addition, on the plane, the first pixel PX1 and the third pixel PX3 may be arranged adjacent to each other along the second direction DR2, and the second pixel PX2 and the fourth pixel PX4 may be arranged adjacent to each other.

One first micro lens MLZ1 may be disposed on the first pixel PX1 and the second pixel PX2 adjacent to each other along the first direction DR1, and one second micro lens MLZ2 may be disposed on the third pixel PX3 and the fourth pixel PX4 adjacent to each other along the first direction DR1. For example, the first pixel PX1 and the second pixel PX2 may share the first micro lens MLZ1, and the third pixel PX3 and the fourth pixel PX4 may share the second micro lens MLZ2.

Each of the first pixel PX1, the second pixel PX2, the third pixel PX3, and the fourth pixel PX4 may have a first length DL1 along the first direction DR1 and a second length DL2 along the second direction DR2. The first length DL1 and the second length DL2 may be substantially the same, and the ratio of the second length DL2 to the first length DL1 may be about 0.9 to about 1.1.

The first micro lens MLZ1 shared by the first pixel PX1 and the second pixel PX2 and the second micro lens MLZ2 shared by the third pixel PX3 and the fourth pixel PX4 may have a third length DL3 along the direction DR1 and the second length DL2 along the second direction DR2. The third length DL3 may be about twice the second length DL2, and the ratio of the third length DL3 to the second length DL2 may be about 1.8 to about 2.2.

The plurality of pixels PX1, PX2, PX3 and PX4 may be distinguished by a pixel isolation structure DTI. The pixel isolation structure DTI may be connected to each other and disposed to surround the first pixel PX1, the second pixel PX2, the third pixel PX3, and the fourth pixel PX4. For example, the pixel isolation structure DTI may be comprised of segments and each of the segments may be directly connected to adjacent segments of the pixel isolation structure DTI to surround the first pixel PX1, the second pixel PX2, the third pixel PX3, and the fourth pixel PX4. The pixel isolation structure DTI may prevent crosstalk between the plurality of pixels PX1, PX2, PX3, and PX4. The pixel isolation structure DTI may be disposed in a deep trench DT.

The pixel isolation structure DTI may not be disposed in a part of the region between the first pixel PX1 and the second pixel PX2 that are adjacent to each other and share the first micro lens MLZ1. Similarly, the pixel isolation structure DTI may not be disposed in a portion of the region between the third pixel PX3 and the fourth pixel PX4 that are adjacent to each other and share the second micro lens MLZ2.

The pixel isolation structure DTI may include a first portion DTI1 disposed in the outer portion to surround the first pixel PX1, second pixel PX2, third pixel PX3, and fourth pixel PX4, a second portion DTI2 connected to the first portion DTI1 and extending parallel to the first direction DR1 and disposed between the first and second pixels PX1 and PX2 and the third and fourth pixels PX3 and PX4, a third portion DTI3 connected to the second portion DTI2 and extending parallel to the second direction DR2 and disposed between the first pixel PX1 and second pixel PX2 and between the third pixel PX3 and fourth pixel PX4, a fourth portion DTI4 connected to the first portion DTI1 and extending parallel to the second direction DR2 and disposed between the first pixel PX1 and second pixel PX2 and between the third pixel PX3 and fourth pixel PX4. The second portion DTI2 may be directly connected to the first portion DTI1, the third portion DTI3 may be directly connected to the second portion DTI2, and the fourth portion DTI4 may be directly connected to the first portion DTI1.

The third portion DTI3 and the fourth portion DTI4 of the pixel isolation structure DTI may be spaced apart from each other without being directly connected to each other.

In the region between the first pixel PX1 and the second pixel PX2, which are adjacent to each other and share the first micro lens MLZ1, there may not be the pixel isolation structure DTI disposed in the region between the third portion DTI3 and the fourth portion DTI4. The region between the first pixel PX1 and the second pixel PX2 where the pixel isolation structure DTI is not disposed may overlap with the center portion of the first micro lens MLZ1.

Similarly, in the region between the third pixel PX3 and the fourth pixel PX4, which are adjacent to each other and share the second micro lens MLZ2, there may not be the pixel isolation structure DTI disposed in the region between the third portion DTI3 and the fourth portion DTI4. The region between the third pixel PX3 and the fourth pixel PX4 where the pixel isolation structure DTI is not disposed may overlap with the center portion of the second micro lens MLZ2.

According to the embodiment, the first pixel PX1, the second pixel PX2, the third pixel PX3, and the fourth pixel PX4 may include a color filter CF that displays the same color. The color filter CF may have a length of approximately twice the first length DL1 along the first direction DR1, and a length of approximately twice the second length DL2 along the second direction DR2. The length of approximately twice the second length DL2 may equal to the third length DL3.

The plurality of pixels PX1, PX2, PX3, and PX4 may include a plurality of gates TG1, TG2, TG3, TG4, SFG, SEG, RG, and DCG. The plurality of gates TG1, TG2, TG3, TG4, SFG, SEG, RG, and DCG may include transfer gates TG1, TG2, TG3 and TG4, a drive gate SFG, a selection gate SEG, a reset gate RG, and a dual conversion gate DCG.

The transfer gates TG1, TG2, TG3, and TG4 may include the first transfer gate TG1 disposed at the first pixel PX1, the second transfer gate TG2 disposed at the second pixel PX2, the third transfer gate TG3 disposed at the third pixel PX3, and the fourth transfer gate TG4 disposed at the fourth pixel PX4.

The first transfer gate TG1 may include two transfer gates TG11 and TG12, the second transfer gate TG2 may include two transfer gates TG21 and TG22, and the third transfer gate TG3 may include two transfer gates TG31 and TG32, and the fourth transfer gate TG4 may include two transfer gates TG41 and TG42. However, the embodiment is not limited thereto.

The first transfer gate TG1 may be the gate electrode of the first transfer transistor Tx1, the second transfer gate TG2 may be the gate electrode of the second transfer transistor Tx2, the third transfer gate TG3 may be the gate electrode of the third transfer transistor Tx3, and the fourth transfer gate TG4 may be the gate electrode of the fourth transfer transistor Tx4. However, the embodiment is not limited thereto.

The first transfer gate TG1 and the second transfer gate TG2 may overlap a first sub-floating diffusion region FD11, and the third transfer gate TG3 and the fourth transfer gate TG4 may overlap a second sub-floating diffusion region FD12.

The first sub-floating diffusion region FD11 and the second sub-floating diffusion region FD12 may form a first floating diffusion region FD1.

Although not shown, the first sub-floating diffusion region FD11 and the second sub-floating diffusion region FD12 may be connected to each other through different layers.

As described above, the pixel isolation structure DTI may not be disposed in the region between the third portion DTI3 and the fourth portion DTI4 of the region between the first pixel PX1 and the second pixel PX2 sharing the first micro lens MLZ1, the first sub-floating diffusion region FD11 disposed at the first pixel PX1 and the second pixel PX2 may be directly connected through the region between the third portion DTI3 and the fourth portion DTI4 without being separated by the pixel isolation structure DTI. The first sub-floating diffusion region FD11 between the first pixel PX1 and the second pixel PX2 may overlap the center portion of the first micro lens MLZ1.

Similarly, the pixel isolation structure DTI may not be disposed in the region between the third portion DTI3 and the fourth portion DTI4 of the region between the third pixel PX3 and the fourth pixel PX4 sharing the second micro lens MLZ2, the second sub-floating diffusion region FD12 disposed in the third pixel PX3 and the fourth pixel PX4 may be directly connected through the region between the third portion DTI3 and the fourth portion DTI4 without being separated by the pixel isolation structure DTI.

The second sub-floating diffusion region FD12 between the third pixel PX3 and the fourth pixel PX4 may overlap the center portion of the second micro lens MLZ2.

As described above, the pixels PX1 to PX4 of one pixel group PG may share a reset transistor RST, a dual conversion transistor DC, a driving transistor Dx, and a selection transistor SEL.

The reset gate RG disposed at the first pixel PX1 may form the reset transistor RST with an active region AR1, the drive gate SFG disposed at the second pixel PX2 may form the drive transistor Dx with an active region AR2, the dual conversion gate DCG disposed at the third pixel PX3 may form the dual conversion transistor DC with an active region AR3, and the selection gate SEG disposed at the fourth pixel PX4 may form the selection transistor SEL with an active region AR4.

Although not shown, the active region AR1 disposed in the first pixel PX1 and the active region AR3 disposed in the third pixel PX3 may be connected to each other through different layers. Similarly, the active region AR2 disposed in the second pixel PX2 and the active region AR4 disposed in the fourth pixel PX4 may be connected to each other through different layers.

The positions of the reset gate RG, drive gate SFG, dual conversion gate DCG, and selection gate SEG are not limited thereto, and the positions of the reset gate RG, drive gate SFG, dual conversion gate DCG, and selection gate SEG may be changed in various ways so that the plurality of pixels PX1, PX2, PX3, and PX4 may share the reset gate RG, drive gate SFG, dual conversion gate DCG, and selection gate SEG.

Referring to FIGS. 5 and 6 along with FIGS. 1 to 4, the image sensor 100 may include a substrate 200. The substrate 200 may include silicon (Si), germanium (Ge), or silicon (Si)-germanium (Ge). The substrate 200 may include gallium arsenide (GaAs), indium phosphide (InP), gallium phosphide (GaP), indium arsenide (InAs), indium antimony (InSb), or indium gallium arsenide (InGaAs). The substrate 200 may include zinc telluride (ZnTe) or cadmium sulfide (CdS).

The substrate 200 may be bulk silicon or silicon-on-insulator (SOI). The substrate 200 may be a silicon substrate, or may include other materials such as silicon germanium, indium antimonide, lead telluride, indium arsenide, indium phosphide, gallium arsenide, or gallium antimonide. Alternatively, the substrate 200 may have an epitaxial layer formed on a base substrate.

The substrate 200 may include a first surface SFA and a second surface SFB opposite to each other.

The substrate 200 includes a deep trench DT, and a pixel isolation structure DTI may be disposed in the deep trench DT of the substrate 200. At least a part of the deep trench DT may be surrounded by a device isolation layer STL disposed in a shallow trench ST. The shallow trench ST may be formed in the first surface SFA of the substrate 200, and the device isolation layer STL may be adjacent to the first surface SFA.

The pixel isolation structure DTI may surround the pixels PX1, PX2, PX3, and PX4, and the plurality of pixels PX1, PX2, PX3, and PX4 may be distinguished by the pixel isolation structure DTI.

As described above, the pixel isolation structure DTI may not be disposed in a part of the region between the first pixel PX1 and the second pixel PX2 that are adjacent to each other and share the first micro lens MLZ1. Similarly, the pixel isolation structure DTI may not be disposed in a portion of the region between the third pixel PX3 and the fourth pixel PX4 that are adjacent to each other and share the second micro lens MLZ2.

The deep trench DT and the pixel isolation structure DTI may be disposed to penetrate the substrate 200 from the first surface SFA to the second surface SFB of the substrate 200. For example, the depth of the deep trench DT along the third direction DR3, which is the height direction, may be substantially equal to the thickness of the substrate 200.

The pixel isolation structure DTI may include an insulating pattern DTIP1, a conductive pattern DTIP2, and a capping pattern DTIP3. The insulating pattern DTIP1 may cover the inner wall of the deep trench DT. The capping pattern DTIP3 may fill the top of the deep trench DT. Side surfaces of the capping pattern DTIP3 may contact side surfaces of the insulating pattern DTIP1. The conductive pattern DTIP2 may fill the bottom of the deep trench DT. Side surfaces of the conductive pattern DTIP2 may contact side surfaces of the insulating pattern DTIP1, and an upper surface of the conductive pattern DTIP2 may contact a lower surface of the capping pattern DTIP3. The top surface of the capping pattern DTIP3 may be coplanar with the first surface SFA of the substrate 200, and the bottom surface of the conductive pattern DTIP2 may be coplanar with the second surface SFB of the substrate 200. The insulating pattern DTIP1 may extend from the first surface SFA to the second surface SFB of the substrate 200. The top surface of the insulating pattern DTIP1 may be coplanar with the first surface SFA of the substrate 200, and the bottom surface of the insulating pattern DTIP1 may be coplanar with the second surface SFB of the substrate 200. The conductive pattern DTIP2 may be separated from the substrate 200 by the insulating pattern DTIP1. In another embodiment, the capping pattern DTIP3 may be omitted.

The conductive pattern DTIP2 may be formed of or include, for example, a semiconductor material such as n-type or p-type doped polysilicon or a metal material. The insulating pattern DTIP1 and the capping pattern DTIP3 may be formed of or include silicon oxide, silicon nitride, or silicon oxynitride. The insulating pattern DTIP1 may be formed of or include a metal oxide such as hafnium oxide, aluminum oxide, or tantalum oxide. In this case, the insulating pattern DTIP1 may function as a negative fixed charge layer.

The photoelectric conversion regions PD1, PD2, PD3, and PD4 corresponding to the respective pixels PX1, PX2, PX3, and PX4 may be positioned in the substrate 200.

Light incident from the outside may be converted into electrical signals in the photoelectric conversion regions PD1, PD2, PD3, and PD4. The photoelectric conversion regions PD1, PD2, PD3, and PD4 may include photodiodes formed inside the substrate 200. The photoelectric conversion regions PD1, PD2, PD3, and PD4 may be doped with a conductive impurity different from the conductive impurity doped in the substrate 200.

The pixel isolation structure DTI may be disposed between the photoelectric conversion regions PD1, PD2, PD3, and PD4 corresponding to the plurality of pixels PX1, PX2, PX3, and PX4, so that the photoelectric conversion regions PD1, PD2, PD3, and PD4 corresponding to the plurality of pixels P1, P2, P3, and P4 may be separated from each other by the pixel isolation structure DTI. The pixel isolation structure DTI may electrically and optically isolate adjacent photoelectric conversion regions PD1, PD2, PD3, and PD4 from each other.

A plurality of gates TG1, TG2, TG3, TG4, SFG, SEG, RG, and DCG may be disposed on the first surface SFA of the substrate 200.

The substrate 200 may have a plurality of active regions AR1, AR2, AR3, and AR4 disposed adjacent to the first surface SFA, a plurality of floating diffusion regions FD11 and FD12 disposed adjacent to the first surface SFA, and a plurality of ground regions (not shown) disposed adjacent to the first surface SFA. The plurality of active regions AR1, AR2, AR3 and AR4 and the plurality of floating diffusion regions FD11 and FD12 may be defined by the device isolation layer STL.

The plurality of active regions AR1, AR2, AR3, and AR4 and the plurality of floating diffusion regions FD11 and FD12 may be doped with impurities. The plurality of active regions AR1, AR2, AR3, and AR4 and the plurality of floating diffusion regions FD11 and FD12 may have a conductivity type opposite to the conductivity type of the substrate 200.

The plurality of active regions AR1, AR2, AR3, and AR4 may include source regions and drain regions of the reset transistor RST, the dual conversion transistor DC, the driving transistor Dx, and the selection transistor SEL.

The plurality of floating diffusion regions FD11 and FD12 may be adjacent to each of the transfer gates TG1, TG2, TG3, and TG4. The plurality of floating diffusion regions FD11 and FD12 may include the first sub-floating diffusion region FD11 overlapping the first transfer gate TG1 of the first pixel PX1 and the second transfer gate TG2 of the second pixel PX2, and the second sub-floating diffusion region FD12 overlapping the third transfer gate TG3 of the third pixel PX3 and the fourth transfer gate TG4 of the fourth pixel PX4. The first sub-floating diffusion region FD11 and the second sub-floating diffusion region FD12 may form the first floating diffusion region FD1.

The first sub-floating diffusion region FD11 and the second sub-floating diffusion region FD12 may not overlap the device isolation layer STL and the pixel isolation structure DTI along the third direction DR3, which is the height direction.

As shown in FIG. 5, the first sub-floating diffusion region FD11 of the first pixel PX1 and the first sub-floating diffusion region FD11 of the second pixel PX2 may be integrally formed in a region where the device isolation layer STL and the pixel isolation structure DTI are not disposed, from a certain depth of the first surface SFA of the substrate 200.

Through this, the first sub-floating diffusion region FD11 of the first pixel PX1 and the first sub-floating diffusion region FD11 of the second pixel PX2 may be an integrated region directly connected to each other.

Similarly, the second sub-floating diffusion region FD12 of the third pixel PX3 and the second sub-floating diffusion region FD12 of the fourth pixel PX4 may be integrally formed in a region where the device isolation layer STL and the pixel isolation structure DTI are not disposed, from a certain depth of the first surface SFA of the substrate 200. Through this, the first sub-floating diffusion region FD12 of the third pixel PX3 and the second sub-floating diffusion region FD12 of the fourth pixel PX4 may be an integrated region directly connected to each other.

Thus, according to the embodiment, the pixel isolation structure DTI may not be disposed in some regions between the first pixel PX1 and the second pixel PX2 that are adjacent and share the first micro lens MLZ1, and the first sub-floating diffusion region FD11 of the first pixel PX1 and the first sub-floating diffusion region FD11 of the second pixel PX2 may be disposed in the region where the pixel isolation structure DTI is not disposed between the first pixel PX1 and the second pixel PX2.

Similarly, the pixel isolation structure DTI may not be disposed in some regions between the third pixel PX3 and the fourth pixel PX4 that are adjacent and share the second micro lens MLZ2, and the second sub-floating diffusion region FD12 of the third pixel PX3 and the second sub-floating diffusion region FD12 of the fourth pixel PX4 may be disposed in the region where the pixel isolation structure DTI is not disposed between the third pixel PX3 and the fourth pixel PX4.

The plurality of gates TG1, TG2, TG3, TG4, SFG, SEG, RG, and DCG, the plurality of active regions AR1, AR2, AR3, and AR4, and the plurality of floating diffusion regions FD11 and FD12 may form the transfer transistors Tx1 to Tx4, the reset transistor RST, the dual conversion transistor DC, the driving transistor Dx, and the selection transistor SEL.

The plurality of ground regions may be doped with conductive impurities, such as the conductive impurities doped in the substrate 200, and the concentration of the doped conductive impurities may be higher than that of the other substrates 200.

The plurality of ground regions may be ground pattern for grounding at least one of the transfer transistors Tx1 to Tx4, the reset transistor RST, the dual conversion transistor DC, the driving transistor Dx, and the selection transistor SEL.

A first structure 300 may be disposed on the first surface SFA of the substrate 200. The first structure 300 may include a plurality of vias ML1, a plurality of wiring layers ML2 and ML3, and a plurality of insulating layers IL1, IL2, and IL3. The plurality of wiring layers ML2 and ML3 may be connected to the plurality of vias ML1. In some embodiments, the plurality of wiring layers ML2 may contact the plurality of vias ML1. The plurality of insulating layers IL1, IL2, and IL3 may electrically separate the plurality of vias ML1 and the plurality of wiring layers ML2 and ML3.

The plurality of vias ML1 and the plurality of wiring layers ML2 and ML3 may be electrically connected to transistors on the first surface SFA of the substrate 200.

The plurality of vias ML1 and the plurality of wiring layers ML2 and ML3 may be formed of or include tungsten, aluminum, copper, tungsten silicide, titanium silicide, tungsten nitride, titanium nitride, doped polysilicon, or the like.

The plurality of insulating layers IL1, IL2, and IL3 may be formed of or include an insulating material such as silicon oxide, silicon nitride, silicon oxynitride, or a low-k material. The low-k dielectric material may be formed of or include, for example, at least one of flowable oxide (FOX), torene silazene (TOSZ), undoped silica glass (USG), borosilica glass (BSG), phosphosilica glass (PSG), borophosphosilica glass (BPSG), plasma enhanced tetraethyl orthosilicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SILK, polyimide, or porous polymeric material, and combinations thereof.

Although not shown, the first sub-floating diffusion region FD11 and the second sub-floating diffusion region FD12 may be connected to each other through at least some of the plurality of vias ML1 and the plurality of wiring layers ML2 and ML3 of the first structure 300.

Although not shown, the active region AR1 disposed at the first pixel PX1 and the active region AR3 disposed at the third pixel PX3 may be separated by the device isolation layer STL and the pixel isolation structure DTI, the active region AR1 disposed at the separated first pixel PX1 and the active region AR3 disposed at the third pixel PX3 may be connected to each other through at least some of the plurality of vias ML1 and the plurality of wiring layers ML2 and ML3 of the first structure 300.

Similarly, the active region AR2 disposed at the second pixel PX2 and the active region AR4 disposed at the fourth pixel PX4 may be separated by the device isolation layer STL and the pixel isolation structure DTI, the active region AR2 disposed at the separated second pixel PX2 and the active region AR4 disposed at the fourth pixel PX4 may be connected to each other through at least some of the plurality of vias ML1 and the plurality of wiring layers ML2 and ML3 of the first structure 300.

The image sensor 100 may further include a support substrate 400 disposed on the first structure 300, but the support substrate 400 may be omitted. An adhesive member (not shown) may be further disposed between the support substrate 400 and the first structure 300.

An anti-reflection layer ARL may be disposed on the second surface SFB of the substrate 200. The anti-reflection layer ARL may cover the second surface SFB of the substrate 200 and the pixel isolation structure DTI.

The anti-reflection layer ARL may be formed of or include, hafnium oxide (HfO₂), silicon oxide (SiO₂), silicon nitride (SiN), aluminum oxide (Al₂O₃), zirconium oxide (ZrO₂), tantalum oxide (Ta₂O₅), titanium oxide (TiO₂), lanthanum oxide (La₂O₃), praseodymium oxide (Pr₂O₃), cerium oxide (CeO₂), neodymium oxide (Nd₂₀₃), promethium oxide (Pm₂O₃), samarium oxide

(Sm₂O₃), europium oxide (Eu₂O₃), gadolinium oxide (Gd₂O₃), terbium oxide (Tb₂O₃), dysprosium oxide (Dy₂O₃), holmium oxide (HO₂O₃), thulium oxide (Tm₂O₃), ytterbium oxide (Yb₂O₃), lutetium oxide (Lu₂O₃), yttrium oxide (Y₂O₃), or a combination thereof.

In an embodiment, the anti-reflection layer ARL may include a plurality of layers including different materials and having different thicknesses. For example, the anti-reflective layer ARL may include first to third anti-reflective layers sequentially stacked on the second surface SFB of the substrate 200.

For example, the first anti-reflection layer may be a fixed charge layer having a negative fixed charge. Hole accumulation may occur in the periphery of the fixed charge layer. Thus, it is possible to effectively reduce a dark current and a white spot.

The third anti-reflection layer may be formed of or include a metal oxide or metal fluoride including at least one of hafnium (Hf), zirconium (Zr), aluminum (Al), tantalum (Ta), titanium (Ti), and yttrium (Y). For example, the first anti-reflection layer and the third anti-reflection layer may be formed of or include a hafnium oxide layer, and the second anti-reflection layer may be formed of or include silicon oxide and/or silicon nitride. However, in another embodiment, the number and relative thickness of the layers included in the anti-reflection layer ARL may be variously modified.

In addition, in another embodiment, the anti-reflection layer ARL may further include a silicon nitride layer disposed between the second anti-reflection layer and the third anti-reflection layer.

Fence patterns IS may be disposed under the anti-reflection layer ARL. On one plane formed by the first and second directions DR1 and DR2, the fence patterns IS may extend along a portion of the pixel isolation structure DTI, and a portion of the pixel isolation structure DTI may overlap the fence patterns IS along a third direction DR3, which is a height direction.

The fence patterns IS may surround the color filters CF. In example embodiments, the fence patterns IS may contact side surfaces of the color filters CF. In some embodiments, a height of the fence patterns IS in the third direction DR3 may be the same as a height of the color filters CF in the third direction DR3. For example, upper surfaces of the fence patterns IS and the color filters CF may be at the same level, and lower surfaces of the fence patterns IS and the color filters CF may be at the same level.

The fence patterns IS may include a low refractive index material. A low refractive index material may have a refractive index greater than about 1.0 and less than or equal to about 1.4. For example, the low refractive index material may include polymethylmethacrylate (PMMA), silicon acrylate (silicon acrylate), cellulose acetatebutyrate (CAB), silica, or fluoro-silicon acrylate (FSA). For example, the low refractive index material may include a polymer material in which silica (SiOx) particles are dispersed.

When the fence patterns IS include a low refractive index material having a relatively low refractive index, light incident toward the fence patterns IS may be totally reflected and directed toward the center of each of the pixel regions P1, P2, P3, and P4.

The fence patterns IS may prevent light obliquely incident into the color filter CF disposed in one of the plurality of pixel regions PX1, PX2, PX3, and PX4 from entering the color filter CF disposed in adjacent pixel regions PX1, PX2, PX3, and/or PX4. Accordingly, crosstalk between the plurality of pixel regions PX1 to PX4 may be prevented.

The plurality of color filters CF may be disposed on the anti-reflection layer ARL and may be separated from each other by the fence pattern IS. The plurality of color filters CF may include, for example, a green filter, a blue filter, and a red filter. The plurality of color filters CF may include, for example, cyan, magenta, or yellow.

The micro lenses MLZ1 and MLZ2 may be disposed on the color filter CF and fence pattern IS. On a plane formed by the first direction DR1 and the second direction DR2, the micro lenses MLZ1 and MLZ2 may overlap two pixels.

The first micro lens MLZ1 may be disposed at the first pixel PX1 and the second pixel PX2 adjacent to each other along the first direction DR1, and the second micro lens MLZ2 may be disposed at the third pixel PX3 and the fourth pixel PX4 adjacent to each other along the first direction DR1.

The micro lenses MLZ1 and MLZ2 may have a convex shape to converge light incident on the corresponding two pixels.

The micro lenses MLZ1 and MLZ2 may be transparent. The micro lenses MLZ1 and MLZ2 may be made of a resin-based material such as, for example, a styrene-based resin, an acryl-based resin, a styrene-acrylic copolymer resin, or a siloxane-based resin.

The micro lenses MLZ1 and MLZ2 condense incident light, and the condensed light may be incident to the photoelectric conversion regions PD1, PD2, PD3, and PD4 through the color filter CF.

A capping layer CPL may be disposed on the micro lenses MLZ1 and MLZ2 to protect the micro lens MLZ.

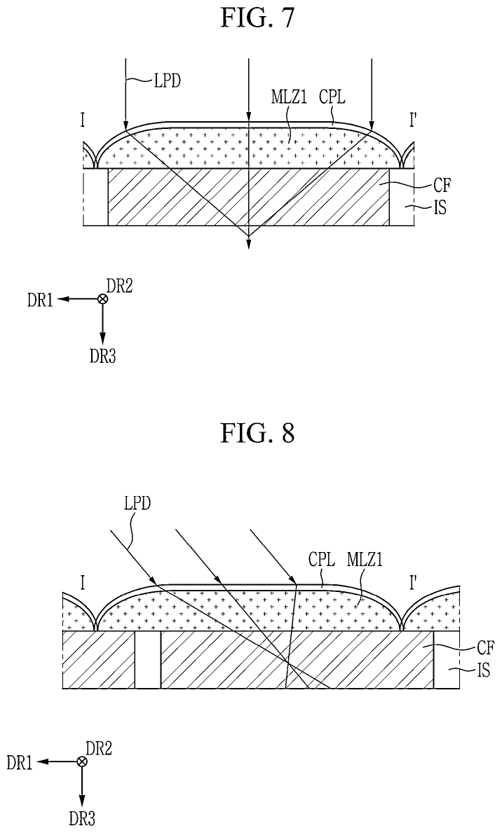

Then, with reference to FIGS. 7 and 8, the optical axis direction of the image sensor according to an example embodiment will be described. FIGS. 7 and 8 are diagrams illustrating the optical axis direction of an image sensor according to an embodiment.

Referring to FIG. 7, according to an embodiment, the center of the micro lens MLZ1 may be arranged to coincide with the center of the color filter CF along the third direction DR3, which is the height direction.

Incident light incident from the outside toward the micro lens MLZ1 may be incident along an optical axis direction LPD. The optical axis direction LPD may be the main incident direction of incident light incident toward the micro lens MLZ1 from the outside.

Referring to FIG. 7, the optical axis direction LPD may be substantially parallel to the third direction DR3, which is the height direction.

Referring to FIG. 5 together with FIG. 7, the incident light incident from the outside toward the micro lens MLZ1 in the optical axis direction LPD may be condensed while passing through the micro lens MLZ1 and incident to the photoelectric conversion regions PD1 and PD2.

Referring to FIG. 8, the center of the micro lens MLZ1 may not coincide with the center portion of the color filter CF along the third direction DR3, which is the height direction, and compared to FIG. 7, the center of the micro lens MLZ1 may be shifted and arranged along the first direction DR1. Although not shown, the micro lens MLZ1 may be shifted and disposed along the second direction DR2. For example, the micro lens MLZ1 may be shifted and disposed along a horizontal direction parallel to the first surface SFA or the second surface SFB of the substrate 200.

The incident light incident towards the micro lens MLZ1 from the outside may incident along the optical axis direction LPD, and the optical axis direction LPD may be the main incident direction of incident light incident towards the micro lens MLZ1 from the outside.

Referring to FIG. 8, unlike the embodiment shown in FIG. 7, the optical axis direction LPD may not be parallel to the third direction DR3, which is the height direction, but may be an inclined direction forming a certain angle with respect to the third direction DR3.

In the optical axis direction LPD, which is a direction inclined to form a certain angle with respect to the third direction DR3, incident light incident on the micro lens MLZ1 from the outside may be condensed while passing through the micro lens MLZ1 and incident on the photoelectric conversion regions PD1 and PD2.

At this time, when the optical axis direction LPD is inclined to form a certain angle with respect to the third direction DR3, the center of the micro lens MLZ1 is shifted and disposed in the horizontal directions DR1 and DR2, so that the incident light may be condensed while passing through the micro lens MLZ1 and incident on the photoelectric conversion regions PD1 and PD2. Even if the optical axis direction LPD is inclined to form a certain angle with respect to the third direction DR3, if the center of the micro lens MLZ1 is arranged to match the center portion of the color filter CF along the third direction DR3, which is the height direction, the incident light may be incident into the photoelectric conversion region after overlapping another adjacent color filter other than the color filter overlapping the micro lens, the color of the light may be mixed, and the condensing ability of the light incident into the photoelectric conversion region may be reduced.

Referring to FIGS. 4 and 5 along with FIGS. 7 and 8, the first sub-floating diffusion region FD11 between the first pixel PX1 and the second pixel PX2 may overlap the center portion of the micro lens MLZ1 along the optical axis direction LPD.

Similarly, the second sub-floating diffusion region FD12 between the third pixel PX3 and the fourth pixel PX4 may overlap the center portion of the second micro lens MLZ2 along the optical axis direction LPD.

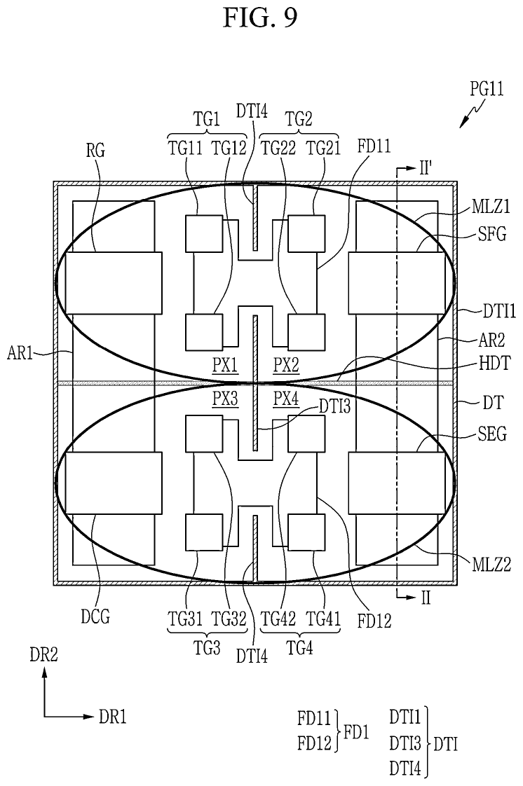

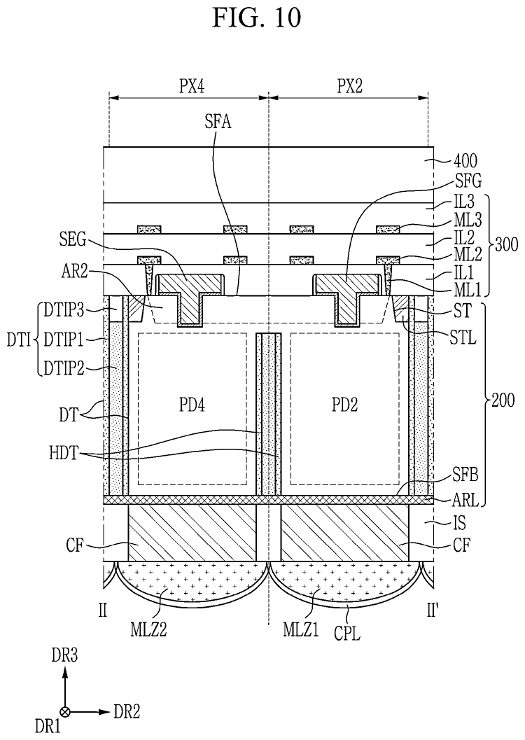

Then, with reference to FIGS. 9 and 10, a pixel group of an image sensor according to another example embodiment will be described. FIG. 9 is a top plan view illustrating a pixel group of an image sensor according to another example embodiment, and FIG. 10 is a cross-sectional view taken along II-II′ line of FIG. 9.

Referring to FIGS. 9 and 10, the pixel group PG11 of the image sensor according to another embodiment is similar to the pixel group PG of the image sensor according to the above-described embodiment. Detailed descriptions of the same constituent elements are not repeated.

The pixel group PG11 of the image sensor according to the embodiment may include a plurality of pixels PX1, PX2, PX3, and PX4.

The plurality of pixels PX1, PX2, PX3, and PX4 may include the first pixel PX1, the second pixel PX2, the third pixel PX3, and the fourth pixel PX4 that are adjacent to each other along the first direction DR1 and the second direction DR2 different from the first direction DR1.

One first micro lens MLZ1 may be disposed on the first pixel PX1 and the second pixel PX2 adjacent to each other along the first direction DR1, and one second micro lens MLZ2 may be disposed on the third pixel PX3 and the fourth pixel PX4 adjacent to each other along the first direction DR1. For example, the first pixel PX1 and the second pixel PX2 may share the first micro lens MLZ1, and the third pixel PX3 and the fourth pixel PX4 may share the second micro lens MLZ2.

The plurality of pixels PX1, PX2, PX3, and PX4 may be distinguished by the pixel isolation structure DTI and a half-pixel isolation structure HDT.

Unlike the pixel group PG of the image sensor described above, the pixel group PG11 of the image sensor according to the embodiment may include the half-pixel isolation structure HDT connected to the first portion DTI1 of the pixel isolation structure DTI instead of the second portion DTI2 of the pixel isolation structure DTI, extending parallel to the first direction DR1, and disposed between the first and second pixels PX1 and PX2 and the third and fourth pixels PX3 and PX4.

The pixel isolation structure DTI may include the first portion DTI1 disposed on the outer portion to surround the first pixel PX1, the second pixel PX2, the third pixel PX3, and the fourth pixel PX4, a third portion DTI3 extending parallel to the second direction DR2 and disposed between the first pixel PX1 and the second pixel PX2 and between the third pixel PX3 and the fourth pixel PX4, and the fourth portion DTI4 connected to the first portion DTI1 and extending parallel to the second direction DR2 and disposed between the first pixel PX1 and the second pixel PX2 and between the third pixel PX3 and the fourth pixel PX4.

The half-pixel isolation structure HDT may extend from the second surface SFB of the substrate 200 along the height direction DR3, but may not extend to the first surface SFA of the substrate 200. The height of the half-pixel isolation structure HDT along the height direction DR3 may be lower than the height of the pixel isolation structure DTI.

The half-pixel isolation structure HDT may be disposed between the first photoelectric conversion region PD1 of the first pixel PX1 and the third photoelectric conversion region PD3 of the third pixel PX3, and between the second photoelectric conversion region PD2 of the second pixel PX2 and the fourth photoelectric conversion region PD4 of the fourth pixel PX4.

Unlike the pixel group PG of the image sensor according to the above-described embodiment, the plurality of active regions of the pixel group PG11 of the image sensor according to the embodiment may include the first active region AR1 disposed at the first pixel PX1 and the third pixel PX3, and the second active region AR2 disposed at the second pixel PX2 and the fourth pixel PX4.

According to the embodiment, the pixel group PG11 of the image sensor may include the half-pixel isolation structure HDT extending in parallel with the first direction DR1 and disposed between the first pixel PX1 and the second pixel PX2 and between the third pixel PX3 and the fourth pixel PX4.

The half-pixel isolation structure HDT may overlap a part of the first active region AR1 disposed at the first pixel PX1 and third pixel PX3 and a part of the second active region AR2 disposed at the second pixel PX2 and fourth pixel PX4. Therefore, the first active region AR1 disposed at the first pixel PX1 and the first active region AR1 disposed at the third pixel PX3 may be directly connected and integrally formed without overlapping the pixel isolation structure DTI.

Similarly, the second active region AR2 disposed at the second pixel PX2 and the second active region AR2 disposed at the fourth pixel PX4 may be directly connected and integrally formed without overlapping the pixel isolation structure DTI.

Similar to the pixel group PG of the image sensor according to the above-described embodiment, the pixel isolation structure DTI of the pixel group PG11 of the image sensor according to the embodiment may not be disposed in the region between the third portion DTI3 and the fourth portion DTI4 of the region between the first pixel PX1 and the second pixel PX2 sharing the first micro lens MLZ1, the first sub-floating diffusion region FD11 disposed at the first pixel PX1 and the second pixel PX2 may be directly connected through the region between the third portion DTI3 and the fourth portion DTI4 without being separated by the pixel isolation structure DTI.

Similarly, the pixel isolation structure DTI may not be disposed in the region between the third portion DTI3 and the fourth portion DTI4 of the region between the third pixel PX3 and the fourth pixel PX4 sharing the second micro lens MLZ2, the second sub-floating diffusion region FD12 disposed in the third pixel PX3 and the fourth pixel PX4 may be directly connected through the region between the third portion DTI3 and the fourth portion DTI4 without being separated by the pixel isolation structure DTI.

The pixels PX1 to PX4 of one pixel group PG11 may share a reset transistor RST, a dual conversion transistor DC, a driving transistor Dx, and a selection transistor SEL.

The reset gate RG disposed at the first pixel PX1 may form the reset transistor RST with the first active region AR1, the drive gate SFG disposed at the second pixel PX2 may form the drive transistor Dx with the second active region AR2, the dual conversion gate DCG disposed at the third pixel PX3 may form the dual conversion transistor DC with the first active region AR1, and the selection gate SEG disposed at the fourth pixel PX4 may form the selection transistor SEL with the second active region AR2.

The positions of the reset gate RG, drive gate SFG, dual conversion gate DCG, and selection gate SEG are not limited thereto, and the positions of the reset gate RG, drive gate SFG, dual conversion gate DCG, and selection gate SEG may be changed in various ways so that the plurality of pixels PX1, PX2, PX3, and PX4 may share the reset gate RG, drive gate SFG, dual conversion gate DCG, and selection gate SEG.

Many features of the image sensor and pixel group according to the embodiment described above with reference to FIGS. 1 to 8 may correspond to the pixel group of the image sensor according to the embodiment.

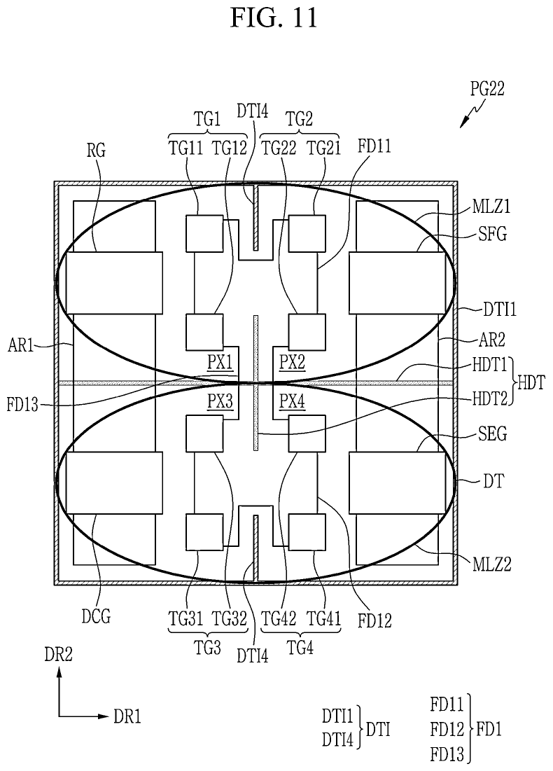

With reference to FIG. 11, a pixel group of an image sensor according to another example embodiment will be described. FIG. 11 is a top plan view illustrating a pixel group of an image sensor according to another example embodiment.

Referring to FIG. 11, the pixel group PG22 of the image sensor according to another embodiment is similar to the pixel groups PG and PG11 of the image sensors according to the above-described embodiment. Detailed descriptions of the same constituent elements are not repeated.

The pixel group PG22 of the image sensor according to the embodiment may include a plurality of pixels PX1, PX2, PX3, and PX4.

The plurality of pixels PX1, PX2, PX3, and PX4 may include the first pixel PX1, the second pixel PX2, the third pixel PX3, and the fourth pixel PX4 that are adjacent to each other along the first direction DR1 and the second direction DR2 different from the first direction DR1.

One first micro lens MLZ1 may be disposed on the first pixel PX1 and the second pixel PX2 adjacent to each other along the first direction DR1, and one second micro lens MLZ2 may be disposed on the third pixel PX3 and the fourth pixel PX4 adjacent to each other along the first direction DR1. For example, the first pixel PX1 and the second pixel PX2 may share the first micro lens MLZ1, and the third pixel PX3 and the fourth pixel PX4 may share the second micro lens MLZ2.

The plurality of pixels PX1, PX2, PX3, and PX4 may be distinguished by the pixel isolation structure DTI and a half-pixel isolation structure HDT.

Unlike the pixel groups PG and PG11 of the image sensors according to the embodiment described above, the pixel group PG22 of the image sensor according to the embodiment may include the half-pixel isolation structure HDT instead of the second portion DTI2 and the third portion DTI3 of the pixel isolation structure DTI.

The pixel isolation structure DTI may include the first portion DTI1 disposed on the outer portion to surround the first pixel PX1, the second pixel PX2, the third pixel PX3, and the fourth pixel PX4, and the fourth portion DTI4 connected to the first portion DTI1 and extending parallel to the second direction DR2 and disposed between the first pixel PX1 and the second pixel PX2 and between the third pixel PX3 and the fourth pixel PX4.

The half-pixel isolation structure HDT may include a first half-pixel isolation structure HDT1, which is connected to the first portion DTI1 of the pixel isolation structure DTI, extends parallel to the first direction DR1, and is disposed between the first and second pixels PX1 and PX2 and the third and fourth pixels PX3 and PX4, and a second half-pixel isolation structure HDT2, which is connected to the first half-pixel isolation structure HDT1, extends parallel to the second direction DR2, and is disposed between the first pixel PX1 and the second pixel PX2 and between the third pixel PX3 and the fourth pixel PX4.

The half-pixel isolation structure HDT may extend from the second surface SFB of the substrate 200 along the height direction DR3, but may not extend to the first surface SFA of the substrate 200. The height of the half-pixel isolation structure HDT along the height direction DR3 may be lower than the height of the pixel isolation structure DTI.

The first half-pixel isolation structure HDT1 of the half-pixel isolation structure HDT may be disposed between the first photoelectric conversion region PD1 of the first pixel PX1 and the third photoelectric conversion region PD3 of the third pixel PX3, and between the second photoelectric conversion region PD2 of the second pixel PX2 and the fourth photoelectric conversion region PD4 of the fourth pixel PX4.

The second half-pixel isolation structure HDT2 of the half-pixel isolation structure HDT may be connected to the first half-pixel isolation structure HDT1 and disposed between the first pixel PX1 and the second pixel PX2 and between the third pixel PX3 and the fourth pixel PX4.

According to the embodiment, the first floating diffusion region FD1 of the pixel group PG22 of the image sensor may include a third sub-floating diffusion region FD13 connected between the first sub-floating diffusion region FD11 and the second sub-floating diffusion region FD12, in addition to the first sub-floating diffusion region FD11 and the second sub-floating diffusion region FD12.

In addition, the plurality of active regions of the pixel group PG22 of the image sensor according to the embodiment may include the first active region AR1 disposed at the first pixel PX1 and the third pixel PX3, and the second active region AR2 disposed at the second pixel PX2 and the fourth pixel PX4.

The first half-pixel isolation structure HDT1 of the half-pixel isolation structure HDT may overlap the first active region AR1 disposed at the first pixel PX1 and third pixel PX3 and a part of the second active region AR2 disposed at the second pixel PX2 and fourth pixel PX4. Therefore, the first active region AR1 disposed at the first pixel PX1 and the first active region AR1 disposed at the third pixel PX3 may be directly connected and integrally formed without overlapping the pixel isolation structure DTI. Similarly, the second active region AR2 disposed at the second pixel PX2 and the second active region AR2 disposed at the fourth pixel PX4 may be directly connected and integrally formed without overlapping the pixel isolation structure DTI.

Further, the center portion of the first half-pixel isolation structure HDT1 and the second half-pixel isolation structure HDT2 of the half-pixel isolation structure HDT may overlap the third sub-floating diffusion region FD13 connected between the first sub-floating diffusion region FD11 and the second sub-floating diffusion region FD12.

Therefore, the first sub-floating diffusion region FD11 and the second sub-floating diffusion region FD12 may be connected to each other through the third sub-floating diffusion region FD13, so that the first sub-floating diffusion region FD11, the second sub-floating diffusion region FD12, and the third sub-floating diffusion region FD13 may be integrally formed without overlapping the pixel isolation structure DTI.

The pixels PX1 to PX4 of one pixel group PG22 may share a reset transistor RST, a dual conversion transistor DC, a driving transistor Dx, and a selection transistor SEL.

The reset gate RG disposed at the first pixel PX1 may form the reset transistor RST with the first active region AR1, the drive gate SFG disposed at the second pixel PX2 may form the drive transistor Dx with the second active region AR2, the dual conversion gate DCG disposed at the third pixel PX3 may form the dual conversion transistor DC with the first active region AR1, and the selection gate SEG disposed at the fourth pixel PX4 may form the selection transistor SEL with the second active region AR2.

The positions of the reset gate RG, drive gate SFG, dual conversion gate DCG, and selection gate SEG are not limited thereto, and the positions of the reset gate RG, drive gate SFG, dual conversion gate DCG, and selection gate SEG may be changed in various ways so that the plurality of pixels PX1, PX2, PX3, and PX4 may share the reset gate RG, drive gate SFG, dual conversion gate DCG, and selection gate SEG.

Many features of the image sensors and pixel groups according to the embodiments described with reference to FIGS. 1 to 10 may correspond to the pixel group of the image sensor according to the embodiment.

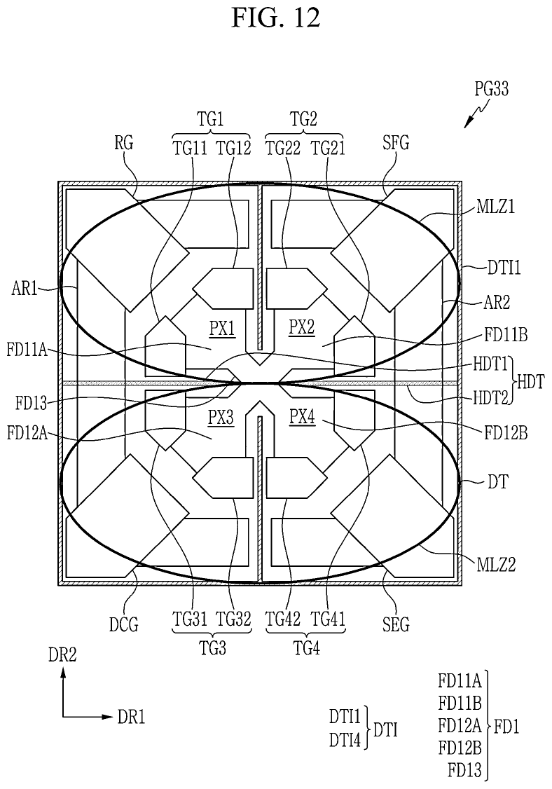

With reference to FIG. 12, a pixel group of an image sensor according to another example embodiment will be described. FIG. 12 is a top plan view illustrating a pixel group of an image sensor according to another example embodiment.

Referring to FIG. 12, a pixel group PG33 of the image sensor according to another embodiment is similar to the pixel groups PG, PG11, and PG22 of the image sensors according to the above-described embodiments. Detailed descriptions of the same constituent elements are not repeated.

The pixel group PG33 of the image sensor according to the embodiment may include the plurality of pixels PX1, PX2, PX3, and PX4.

The plurality of pixels PX1, PX2, PX3, and PX4 may include the first pixel PX1, the second pixel PX2, the third pixel PX3, and the fourth pixel PX4 that are adjacent to each other along the first direction DR1 and the second direction DR2 different from the first direction DR1.

One first micro lens MLZ1 may be disposed on the first pixel PX1 and the second pixel PX2 adjacent to each other along the first direction DR1, and one second micro lens MLZ2 may be disposed on the third pixel PX3 and the fourth pixel PX4 adjacent to each other along the first direction DR1. For example, the first pixel PX1 and the second pixel PX2 may share the first micro lens MLZ1, and the third pixel PX3 and the fourth pixel PX4 may share the second micro lens MLZ2.

The plurality of pixels PX1, PX2, PX3 and PX4 may be distinguished by the pixel isolation structure DTI and a half-pixel isolation structure HDT. Unlike the pixel groups PG and PG11 of the image sensors according to the embodiment described above, the pixel group PG33 of the image sensor according to the embodiment may include the half-pixel isolation structure HDT instead of the second portion DTI2 and the third portion DTI3 of the pixel isolation structure DTI.

The pixel isolation structure DTI may include the first portion DTI1 disposed on the outer portion to surround the first pixel PX1, the second pixel PX2, the third pixel PX3, and the fourth pixel PX4, and the fourth portion DTI4 connected to the first portion DTI1 and extending parallel to the second direction DR2 and disposed between the first pixel PX1 and the second pixel PX2 and between the third pixel PX3 and the fourth pixel PX4.

The half-pixel separation structure HDT may include the first half-pixel isolation structure HDT1, which is connected with the first portion DT1 of the pixel isolation structure DTI, extending parallel to the first direction DR1, and disposed between the first pixel PX1 and the second pixel PX2, and the second half-pixel isolation structure HDT2, which is disposed between the third pixel PX3 and the fourth pixel PX4.

The half-pixel isolation structure HDT may extend from the second surface SFB of the substrate 200 along the height direction DR3, but may not extend to the first surface SFA of the substrate 200. The height of the half-pixel isolation structure HDT along the height direction DR3 may be lower than the height of the pixel isolation structure DTI.

The first half-pixel isolation structure HDT1 of the half-pixel isolation structure HDT may be disposed between the first photoelectric conversion region PD1 of the first pixel PX1 and the third photoelectric conversion region PD3 of the third pixel PX3, and the second half-pixel isolation structure HDT2 may be disposed between the second photoelectric conversion region PD2 of the second pixel PX2 and the fourth photoelectric conversion region PD4 of the fourth pixel PX4.

The first floating diffusion region FD1 of the pixel group PG33 of the image sensor according to the embodiment may include the first sub-floating diffusion region FD11, which includes a first portion FD11A disposed at the first pixel PX1 and a second portion FD11B disposed at the second pixel PX2, the second sub-floating diffusion region FD12, which includes a third portion FD12A disposed at the third pixel PX3 and a fourth portion FD12B disposed at the fourth pixel PX4, and the third sub-floating diffusion region FD13 connected between the first sub-floating diffusion region FD11 and the second sub-floating diffusion region FD12.

The first portion FD11A disposed at the first pixel PX1 of the first sub-floating diffusion region FD11 and the second portion FD11B disposed at the second pixel PX2 may be distinguished by the fourth portion DTI4 of the pixel separation structure DTI, and the third portion FD12A disposed at the third pixel PX3 of the second sub-floating diffusion region FD12 and the fourth portion FD12B disposed at the fourth pixel PX4 may be distinguished by the fourth portion DTI4 of the pixel isolation structure DTI.

The third sub-floating diffusion region FD13 of the first sub-floating diffusion region FD11 may connect the first portion FD11A and the second portion FD11B of the first sub-floating diffusion region FD11, and the third portion FD12A and the fourth portion FD12B of the second sub-floating diffusion region FD12, and may be disposed in the center portion of the plurality of pixels PX1, PX2, PX3, and PX4.

In addition, the plurality of active regions of the pixel group PG33 of the image sensor according to the embodiment may include the first active region AR1 disposed at the first pixel PX1 and the third pixel PX3, and the second active region AR2 disposed at the second pixel PX2 and the fourth pixel PX4.

The first half-pixel isolation structure HDT1 of the half-pixel isolation structure HDT may overlap a part of the first active region AR1 disposed at the first pixel PX1 and the third pixel PX3, and the second half-pixel isolation structure HDT2 of the pixel isolation structure HDT may overlap a part of the second active region AR2 disposed at the second pixel PX2 and the fourth pixel PX4. Therefore, the first active region AR1 disposed at the first pixel PX1 and the first active region AR1 disposed at the third pixel PX3 may be directly connected and integrally formed without overlapping the pixel isolation structure DTI. Similarly, the second active region AR2 disposed at the second pixel PX2 and the second active region AR2 disposed at the fourth pixel PX4 may be directly connected and integrally formed without overlapping the pixel isolation structure DTI.

In addition, the first sub-floating diffusion region FD11 and the second sub-floating diffusion region FD12 may be connected to each other through the third sub-floating diffusion region FD13, so that the first sub-floating diffusion region FD11, the second sub-floating diffusion region FD12, and the third sub-floating diffusion region FD13 may be integrally formed without overlapping the pixel isolation structure DTI.

The pixels PX1 to PX4 of one pixel group PG33 may share a reset transistor RST, a dual conversion transistor DC, a driving transistor Dx, and a selection transistor SEL.

The reset gate RG disposed at the first pixel PX1 may form the reset transistor RST with the first active region AR1, the drive gate SFG disposed at the second pixel PX2 may form the drive transistor Dx with the second active region AR2, the dual conversion gate DCG disposed at the third pixel PX3 may form the dual conversion transistor DC with the first active region AR1, and the selection gate SEG disposed at the fourth pixel PX4 may form the selection transistor SEL with the second active region AR2.

The positions of the reset gate RG, drive gate SFG, dual conversion gate DCG, and selection gate SEG are not limited thereto, and the positions of the reset gate RG, drive gate SFG, dual conversion gate DCG, and selection gate SEG may be changed in various ways so that the plurality of pixels PX1, PX2, PX3, and PX4 may share the reset gate RG, drive gate SFG, dual conversion gate DCG, and selection gate SEG.

Many features of the image sensors and pixel groups according to the embodiments described with reference to FIGS. 1 to 11 may correspond to the pixel group of the image sensor according to the embodiment.

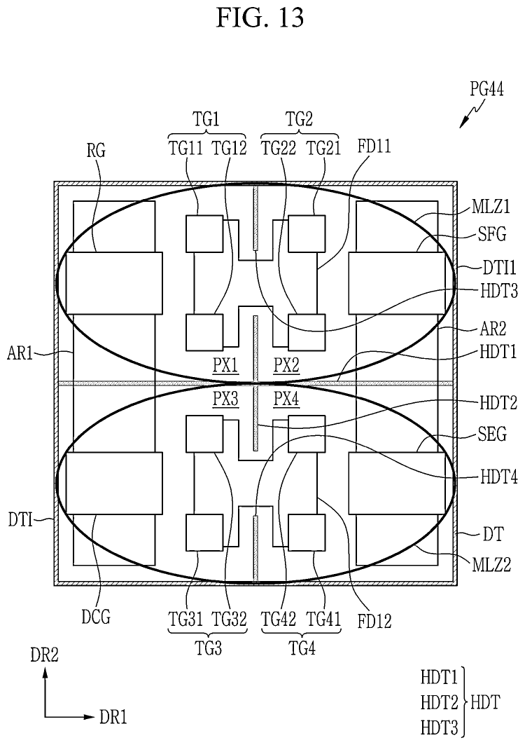

With reference to FIG. 13, a pixel group of an image sensor according to another example embodiment will be described. FIG. 13 is a top plan view illustrating a pixel group of an image sensor according to another example embodiment.

Referring to FIG. 13, a pixel group PG44 of the image sensor according to another embodiment is similar to the pixel groups PG, PG11, PG22 and PG33 of the image sensors according to the above-described embodiments. Detailed descriptions of the same constituent elements are not repeated.

The pixel group PG44 of the image sensor according to the embodiment may include the plurality of pixels PX1, PX2, PX3, and PX4.

The plurality of pixels PX1, PX2, PX3, and PX4 may include the first pixel PX1, the second pixel PX2, the third pixel PX3, and the fourth pixel PX4 that are adjacent to each other along the first direction DR1 and the second direction DR2 different from the first direction DR1.

One first micro lens MLZ1 may be disposed on the first pixel PX1 and the second pixel PX2 adjacent to each other along the first direction DR1, and one second micro lens MLZ2 may be disposed on the third pixel PX3 and the fourth pixel PX4 adjacent to each other along the first direction DR1. For example, the first pixel PX1 and the second pixel PX2 may share the first micro lens MLZ1, and the third pixel PX3 and the fourth pixel PX4 may share the second micro lens MLZ2.

The plurality of pixels PX1, PX2, PX3, and PX4 may be distinguished by the pixel isolation structure DTI and a half-pixel isolation structure HDT.

Unlike the pixel groups PG, PG11, PG22, and PG33 of the image sensors according to the embodiments described above, the pixel group PG44 of the image sensor according to the embodiment may have the pixel isolation structure DTI disposed only on the outer portion to surround the first pixel PX1, the second pixel PX2, the third pixel PX3, and the fourth pixel PX4.

In the pixel group PG44 of the image sensor according to the embodiment, the half-pixel isolation structure HDT may be disposed instead of the second portion DTI2, the third portion DTI3, and the fourth portion DTI4 of the pixel isolation structure DTI.

The half-pixel isolation structure HDT may include the first half-pixel isolation structure HDT1, which is connected to the pixel isolation structure DTI, extends parallel to the first direction DR2, and is disposed between the first pixel PX1 and the second pixel PX2 and between the third pixel PX3 and the fourth pixel PX4, the second half-pixel isolation structure HDT2, which is connected to the first half-pixel isolation structure HDT1, extends parallel to the second direction DR2, and is disposed between the first pixel PX1 and the second pixel PX2 and between the third pixel PX3 and the fourth pixel PX4, and the third half-pixel isolation structure HDT3, which is connected to the pixel isolation structure DTI, extends parallel to the second direction DR2, and is disposed between the first pixel PX1 and the second pixel PX2 and between the third pixel PX3 and the fourth pixel PX4.

The half-pixel isolation structure HDT may extend from the second surface SFB of the substrate 200 along the height direction DR3, but may not extend to the first surface SFA of the substrate 200. The height of the half-pixel isolation structure HDT along the height direction DR3 may be lower than the height of the pixel isolation structure DTI.

The first half-pixel isolation structure HDT1 of the half-pixel isolation structure HDT may be disposed between the first photoelectric conversion region PD1 of the first pixel PX1 and the third photoelectric conversion region PD3 of the third pixel PX3, and between the second photoelectric conversion region PD2 of the second pixel PX2 and the fourth photoelectric conversion region PD4 of the fourth pixel PX4.

The second half-pixel isolation structure HDT2 and the third half-pixel isolation structure HDT3 of the half-pixel isolation structure HDT may be disposed between the first photoelectric conversion region PD1 of the first pixel PX1 and the second photoelectric conversion region PD2 of the second pixel PX2, and between the third photoelectric conversion region PD3 of the third pixel PX3 and the fourth photoelectric conversion region PD4 of the fourth pixel PX4.

The first floating diffusion region FD1 of the pixel group PG44 of the image sensor according to the embodiment may include the first sub-floating diffusion region FD11 and the second sub-floating diffusion region FD12.

The first sub-floating diffusion region FD11 and the second sub-floating diffusion region FD12 of the first floating diffusion region FD1 may not overlap the pixel isolation structure DTI in the third direction DR3. The first sub-floating diffusion region FD11 disposed at the first pixel PX1 and the second pixel PX2 may be directly connected without being separated by the pixel isolation structure DTI, and the second sub-floating diffusion region FD12 disposed at the third pixel PX3 and the fourth pixel PX4 may be directly connected without being separated by the pixel isolation structure DTI.

In addition, the plurality of active regions of the pixel group PG44 of the image sensor according to the embodiment may include the first active region AR1 disposed at the first pixel PX1 and the third pixel PX3, and the second active region AR2 disposed at the second pixel PX2 and the fourth pixel PX4.

The first half-pixel isolation structure HDT1 of the half-pixel isolation structure HDT may overlap a part of the first active region AR1 disposed at the first pixel PX1 and the third pixel PX3, and the second half-pixel isolation structure HDT2 of the pixel isolation structure HDT may overlap a part of the second active region AR2 disposed at the second pixel PX2 and the fourth pixel PX4. Therefore, the first active region AR1 disposed at the first pixel PX1 and the first active region AR1 disposed at the third pixel PX3 may be directly connected and integrally formed without overlapping the pixel isolation structure DTI. Similarly, the second active region AR2 disposed at the second pixel PX2 and the second active region AR2 disposed at the fourth pixel PX4 may be directly connected and integrally formed without overlapping the pixel isolation structure DTI in the third direction DR3.

The pixels PX1 to PX4 of one pixel group PG44 may share a reset transistor RST, a dual conversion transistor DC, a driving transistor Dx, and a selection transistor SEL.

The reset gate RG disposed at the first pixel PX1 may form the reset transistor RST with the first active region AR1, the drive gate SFG disposed at the second pixel PX2 may form the drive transistor Dx with the second active region AR2, the dual conversion gate DCG disposed at the third pixel PX3 may form the dual conversion transistor DC with the first active region AR1, and the selection gate SEG disposed at the fourth pixel PX4 may form the selection transistor SEL with the second active region AR2.

The positions of the reset gate RG, drive gate SFG, dual conversion gate DCG, and selection gate SEG are not limited thereto, and the positions of the reset gate RG, drive gate SFG, dual conversion gate DCG, and selection gate SEG may be changed in various ways so that the plurality of pixels PX1, PX2, PX3, and PX4 may share the reset gate RG, drive gate SFG, dual conversion gate DCG, and selection gate SEG.

Many features of the image sensors and pixel groups according to the embodiments described with reference to FIGS. 1 to 12 may correspond to the pixel group of the image sensor according to the embodiment.

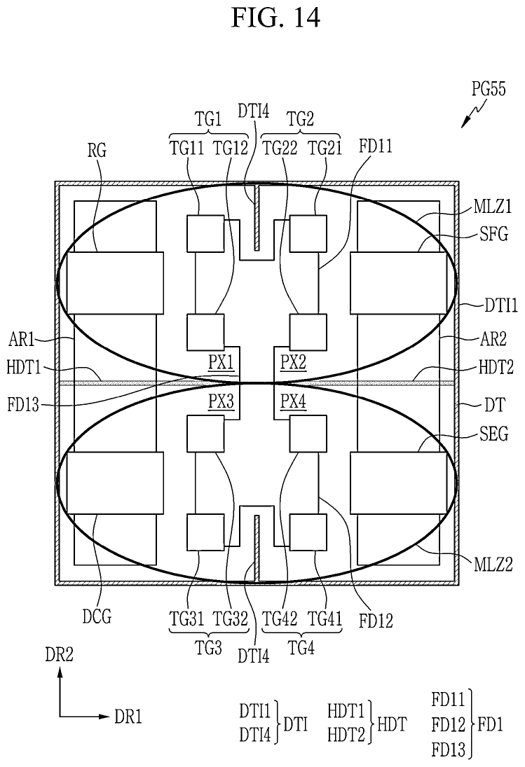

With reference to FIG. 14, a pixel group of an image sensor according to another example embodiment will be described. FIG. 14 is a top plan view illustrating a pixel group of an image sensor according to another example embodiment.

Referring to FIG. 14, a pixel group PG55 of the image sensor according to another embodiment is similar to the pixel groups PG, PG11, PG22, PG33, and PG44 of the image sensors according to the above-described embodiments. Detailed descriptions of the same constituent elements are not repeated.

The pixel group PG55 of the image sensor according to the embodiment may include the plurality of pixels PX1, PX2, PX3, and PX4.

The plurality of pixels PX1, PX2, PX3, and PX4 may include the first pixel PX1, the second pixel PX2, the third pixel PX3, and the fourth pixel PX4 that are adjacent to each other along the first direction DR1 and the second direction DR2 different from the first direction DR1.

One first micro lens MLZ1 may be disposed on the first pixel PX1 and the second pixel PX2 adjacent to each other along the first direction DR1, and one second micro lens MLZ2 may be disposed on the third pixel PX3 and the fourth pixel PX4 adjacent to each other along the first direction DR1. For example, the first pixel PX1 and the second pixel PX2 may share the first micro lens MLZ1, and the third pixel PX3 and the fourth pixel PX4 may share the second micro lens MLZ2.

The plurality of pixels PX1, PX2, PX3, and PX4 may be distinguished by the pixel isolation structure DTI and a half-pixel isolation structure HDT.

The pixel group PG55 of the image sensor according to the embodiment may include the half-pixel isolation structure HDT instead of the second portion DTI2 and the third portion DTI3 of the pixel isolation structure DTI.

The pixel isolation structure DTI may include the first portion DTI1 disposed on the outer portion to surround the first pixel PX1, the second pixel PX2, the third pixel PX3, and the fourth pixel PX4, and the fourth portion DTI4 connected to the first portion DTI1 and extending parallel to the second direction DR2 and disposed between the first pixel PX1 and the second pixel PX2 and between the third pixel PX3 and the fourth pixel PX4.

The half-pixel separation structure HDT may include the first half-pixel isolation structure HDT1, which is connected with the first portion DT1 of the pixel isolation structure DTI, extending parallel to the first direction DR1, and disposed between the first pixel PX1 and the third pixel PX3, and the second half-pixel isolation structure HDT2, which is disposed between the second pixel PX2 and the fourth pixel PX4.

The half-pixel isolation structure HDT may extend from the second surface SFB of the substrate 200 along the height direction DR3, but may not extend to the first surface SFA of the substrate 200. The height of the half-pixel isolation structure HDT along the height direction DR3 may be lower than the height of the pixel isolation structure DTI.

The first half-pixel isolation structure HDT1 of the half-pixel isolation structure HDT may be disposed between the first photoelectric conversion region PD1 of the first pixel PX1 and the third photoelectric conversion region PD3 of the third pixel PX3, and the second half-pixel isolation structure HDT2 of the half-pixel isolation structure HDT may be disposed between the second photoelectric conversion region PD2 of the second pixel PX2 and the fourth photoelectric conversion region PD4 of the fourth pixel PX4.

According to the embodiment, the first floating diffusion region FD1 of the pixel group PG55 of the image sensor may include the third sub-floating diffusion region FD13 connected between the first sub-floating diffusion region FD11 and the second sub-floating diffusion region FD12, in addition to the first sub-floating diffusion region FD11 and the second sub-floating diffusion region FD12.

In addition, the plurality of active regions of the pixel group PG55 of the image sensor according to the embodiment may include the first active region AR1 disposed at the first pixel PX1 and the third pixel PX3, and the second active region AR2 disposed at the second pixel PX2 and the fourth pixel PX4.

The first half-pixel isolation structure HDT1 of the half-pixel isolation structure HDT may overlap the first active region AR1 disposed at the first pixel PX1 and third pixel PX3 and a part of the second active region AR2 disposed at the second pixel PX2 and fourth pixel PX4.

Therefore, the first active region AR1 disposed at the first pixel PX1 and the first active region AR1 disposed at the third pixel PX3 may be directly connected and integrally formed without overlapping the pixel isolation structure DTI. Similarly, the second active region AR2 disposed at the second pixel PX2 and the second active region AR2 disposed at the fourth pixel PX4 may be directly connected and integrally formed without overlapping the pixel isolation structure DTI.

The third sub-floating diffusion region FD13 connected between the first sub-floating diffusion region FD11 and the second sub-floating diffusion region FD12 may not overlap the pixel isolation structure DTI and the half-pixel isolation structure HDT in the third direction DR3.

Therefore, the first sub-floating diffusion region FD11 and the second sub-floating diffusion region FD12 may be connected to each other through the third sub-floating diffusion region FD13, so that the first sub-floating diffusion region FD11, the second sub-floating diffusion region FD12, and the third sub-floating diffusion region FD13 may be integrally formed without overlapping the pixel isolation structure DTI in the third direction DR3.

The pixels PX1 to PX4 of one pixel group PG55 may share a reset transistor RST, a dual conversion transistor DC, a driving transistor Dx, and a selection transistor SEL.

The reset gate RG disposed at the first pixel PX1 may form the reset transistor RST with the first active region AR1, the drive gate SFG disposed at the second pixel PX2 may form the drive transistor Dx with the second active region AR2, the dual conversion gate DCG disposed at the third pixel PX3 may form the dual conversion transistor DC with the first active region AR1, and the selection gate SEG disposed at the fourth pixel PX4 may form the selection transistor SEL with the second active region AR2.

The positions of the reset gate RG, drive gate SFG, dual conversion gate DCG, and selection gate SEG are not limited thereto, and the positions of the reset gate RG, drive gate SFG, dual conversion gate DCG, and selection gate SEG may be changed in various ways so that the plurality of pixels PX1, PX2, PX3, and PX4 may share the reset gate RG, drive gate SFG, dual conversion gate DCG, and selection gate SEG.

Many features of the image sensors and pixel groups according to the embodiments described with reference to FIGS. 1 to 12 may correspond to the pixel group of the image sensor according to the embodiment.

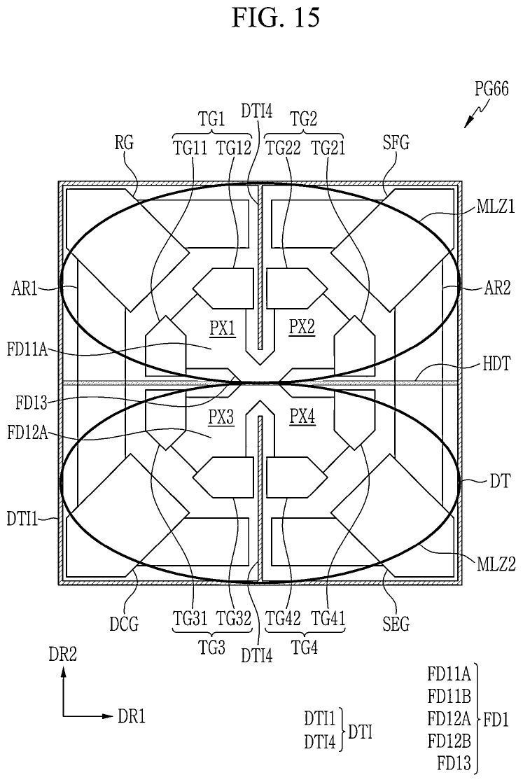

With reference to FIG. 15, a pixel group of an image sensor according to another example embodiment will be described. FIG. 15 is a top plan view illustrating a pixel group of an image sensor according to another example embodiment.

Referring to FIG. 15, a pixel group PG55 of the image sensor according to another embodiment is similar to the pixel groups PG, PG11, PG22, PG33 and PG44 of the image sensors according to the above-described embodiments. Detailed descriptions of the same constituent elements are not repeated.

The pixel group PG66 of the image sensor according to the embodiment may include the plurality of pixels PX1, PX2, PX3, and PX4.

The plurality of pixels PX1, PX2, PX3, and PX4 may include the first pixel PX1, the second pixel PX2, the third pixel PX3, and the fourth pixel PX4 that are adjacent to each other along the first direction DR1 and the second direction DR2 different from the first direction DR1.

One first micro lens MLZ1 may be disposed on the first pixel PX1 and the second pixel PX2 adjacent to each other along the first direction DR1, and one second micro lens MLZ2 may be disposed on the third pixel PX3 and the fourth pixel PX4 adjacent to each other along the first direction DR1. For example, the first pixel PX1 and the second pixel PX2 may share the first micro lens MLZ1, and the third pixel PX3 and the fourth pixel PX4 may share the second micro lens MLZ2.

The plurality of pixels PX1, PX2, PX3, and PX4 may be distinguished by the pixel isolation structure DTI and a half-pixel isolation structure HDT. Unlike the pixel group PG of the image sensor according to the above-described embodiment, the plurality of active regions of the pixel group PG66 of the image sensor according to the embodiment may include the half-pixel isolation structure HDT instead of the second portion DTI2 of the pixel isolation structure DTI.

The pixel isolation structure DTI may include the first portion DTI1 disposed on the outer portion to surround the first pixel PX1, the second pixel PX2, the third pixel PX3, and the fourth pixel PX4, and the fourth portion DTI4 connected to the first portion DTI1 and extending parallel to the second direction DR2 and disposed between the first pixel PX1 and the second pixel PX2 and between the third pixel PX3 and the fourth pixel PX4.

The half-pixel isolation structure HDT may be connected to the first portion DTI1 of the pixel isolation structure DTI, may extend parallel to the first direction DR1, and may be disposed between the first pixel PX1 and the second pixel PX2 and between the third pixel PX3 and the fourth pixel PX4.

The half-pixel isolation structure HDT may extend from the second surface SFB of the substrate 200 along the height direction DR3, but may not extend to the first surface SFA of the substrate 200. The height of the half-pixel isolation structure HDT along the height direction DR3 may be lower than the height of the pixel isolation structure DTI.

The half-pixel isolation structure HDT may be disposed between the first photoelectric conversion region PD1 of the first pixel PX1 and the third photoelectric conversion region PD3 of the third pixel PX3, and between the second photoelectric conversion region PD2 of the second pixel PX2 and the fourth photoelectric conversion region PD4 of the fourth pixel PX4.

The first floating diffusion region FD1 of the pixel group PG66 of the image sensor according to the embodiment may include the first sub-floating diffusion region FD11, which includes a first portion FD11A disposed at the first pixel PX1 and a second portion FD11B disposed at the second pixel PX2, the second sub-floating diffusion region FD12, which includes a third portion FD12A disposed at the third pixel PX3 and a fourth portion FD12B disposed at the fourth pixel PX4, and the third sub-floating diffusion region FD13 connected between the first sub-floating diffusion region FD11 and the second sub-floating diffusion region FD12.

The first portion FD11A disposed at the first pixel PX1 of the first sub-floating diffusion region FD11 and the second portion FD11B disposed at the second pixel PX2 may be distinguished by the fourth portion DTI4 of the pixel separation structure DTI, and the third portion FD12A disposed at the third pixel PX3 of the second sub-floating diffusion region FD12 and the fourth portion FD12B disposed at the fourth pixel PX4 may be distinguished by the fourth portion DTI4 of the pixel isolation structure DTI.

The third sub-floating diffusion region FD13 of the first sub-floating diffusion region FD11 may connect the first portion FD11A and the second portion FD11B of the first sub-floating diffusion region FD11, and the third portion FD12A and the fourth portion FD12B of the second sub-floating diffusion region FD12, and may be disposed in the center portion of the plurality of pixels PX1, PX2, PX3, and PX4.

In addition, the plurality of active regions of the pixel group PG66 of the image sensor according to the embodiment may include the first active region AR1 disposed at the first pixel PX1 and the third pixel PX3, and the second active region AR2 disposed at the second pixel PX2 and the fourth pixel PX4.

The half-pixel isolation structure HDT may overlap in the third direction DR3 a part of the first active region AR1 disposed at the first pixel PX1 and third pixel PX3 and a part of the second active region AR2 disposed at the second pixel PX2 and fourth pixel PX4.

Therefore, the first active region AR1 disposed at the first pixel PX1 and the first active region AR1 disposed at the third pixel PX3 may be directly connected and integrally formed without overlapping the pixel isolation structure DTI in the third direction DR3. Similarly, the second active region AR2 disposed at the second pixel PX2 and the second active region AR2 disposed at the fourth pixel PX4 may be directly connected and integrally formed without overlapping the pixel isolation structure DTI in the third direction DR3.

In addition, the first sub-floating diffusion region FD11 and the second sub-floating diffusion region FD12 may be connected to each other through the third sub-floating diffusion region FD13, so that the first sub-floating diffusion region FD11, the second sub-floating diffusion region FD12, and the third sub-floating diffusion region FD13 may be integrally formed without overlapping the pixel isolation structure DTI in the third direction DR3.

At least a part of the third sub-floating diffusion region FD13 may overlap the half-pixel isolation structure HDT in the third direction DR3.

The pixels PX1 to PX4 of one pixel group PG66 may share a reset transistor RST, a dual conversion transistor DC, a driving transistor Dx, and a selection transistor SEL.

The reset gate RG disposed at the first pixel PX1 may form the reset transistor RST with the first active region AR1, the drive gate SFG disposed at the second pixel PX2 may form the drive transistor Dx with the second active region AR2, the dual conversion gate DCG disposed at the third pixel PX3 may form the dual conversion transistor DC with the first active region AR1, and the selection gate SEG disposed at the fourth pixel PX4 may form the selection transistor SEL with the second active region AR2.

The positions of the reset gate RG, drive gate SFG, dual conversion gate DCG, and selection gate SEG are not limited thereto, and the positions of the reset gate RG, drive gate SFG, dual conversion gate DCG, and selection gate SEG may be changed in various ways so that the plurality of pixels PX1, PX2, PX3, and PX4 may share the reset gate RG, drive gate SFG, dual conversion gate DCG, and selection gate SEG.

Many features of the image sensors and pixel groups according to the embodiments described with reference to FIGS. 1 to 14 may correspond to the pixel group of the image sensor according to the embodiment.

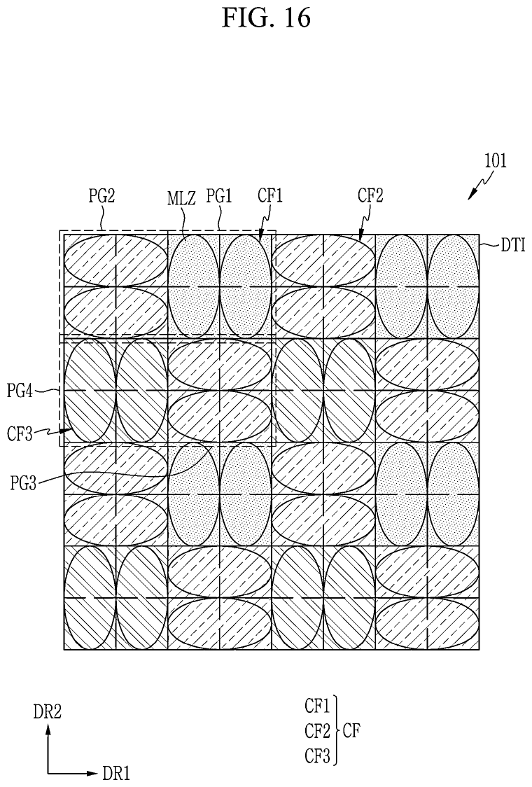

Then, referring to FIG. 16, a pixel arrangement of an image sensor 101 according to an example embodiment will be described. FIG. 16 is a top plan view illustrating a part of an image sensor according to an example embodiment.

Referring to FIG. 16, the pixel arrangement of the image sensor 101 according to the embodiment is similar to the pixel arrangement of the image sensor 100 according to the embodiment described with reference to FIG. 2.

The image sensor 101 according to the embodiment may include pixel groups PG, photodiodes PD, color filters CF, micro lenses MLZ, and other circuits required for operation of the image sensor 101.

The plurality of pixels PX may be grouped in a plurality of columns and a plurality of rows to form one unit pixel group PG.

The pixel group PG overlapping a first color filter CF1 may detect light of a first color, the pixel group PG overlapping a second color filter CF2 may detect light of a second color different from the first color, and the pixel group PG overlapping a third color filter CF3 may detect light of a third color different from the first and second colors.

Each of the plurality of pixel groups PG may include N×M pixels PX in an N×M arrangement. The N and the M may each independently be an integer greater than 1. For example, each of N and M may be 2, and may have a 2×2 tetra structure pixel arrangement in a plan view. For example, each of the plurality of pixel groups PG may include pixels PX arranged in a 2×2 shape in a plan view.

More specifically, the plurality of pixels PX disposed in the arrangement direction of the column line CL and the plurality of pixels PX disposed in the arrangement direction of the row line RL may configure one unit pixel group PG. For example, one unit pixel group PG may include a plurality of pixels PX arranged in two columns and two rows. However, the embodiment is not limited thereto, and the number of pixels PX included in one pixel group PG may be variously modified.

The image sensor 101 according to the embodiment may include a first pixel row in which a first pixel group PG1 corresponding to the first color filter CF1 and a second pixel group PG2 corresponding to the second color filter CF2 are alternately arranged in the first direction DR1, and a second pixel row in which a third pixel group PG3 corresponding to the second color filter CF2 and a fourth pixel group PG4 corresponding to the third color filter CF3 are alternately arranged in the first direction DR1.

Micro lenses MLZ may be disposed one per every two adjacent pixels PX. For example, one micro lens MLZ may be disposed for every two adjacent pixels PX along the first direction DR1, or one micro lens MLZ may be disposed for each two adjacent pixels PX along the second direction DR2.

The first pixel group PG1 may include micro lenses MLZ shared by two adjacent pixels along the second direction DR2, the second pixel group PG2 and the third pixel group PG3 may include micro lenses MLZ shared by two adjacent pixels along the first direction DR1, and the fourth pixel group PG4 may include micro lenses MLZ shared by two adjacent pixels along the second direction DR2.

The first pixel row and the second pixel row may be alternately arranged in a second direction DR2.

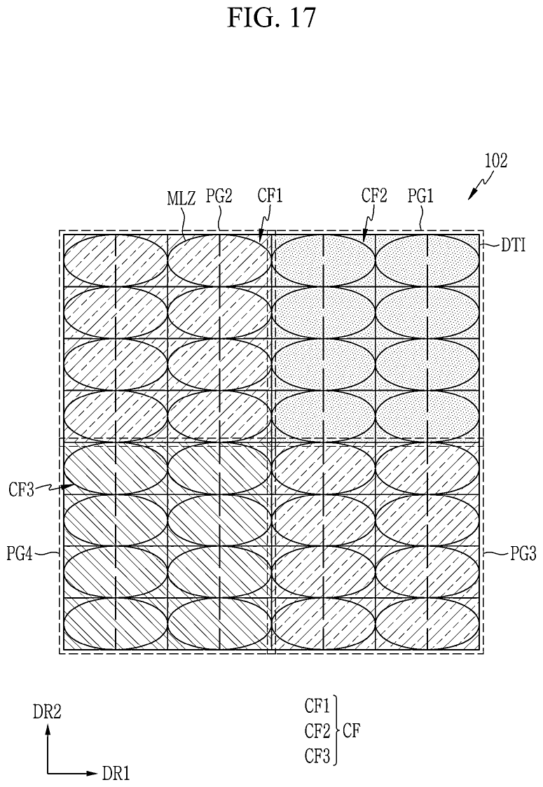

With reference to FIG. 17, pixel arrangement of an image sensor according to an example embodiment will be described. FIG. 17 is a top plan view illustrating a part of an image sensor according to an example embodiment.

Referring to FIG. 17, the pixel arrangement of an image sensor 102 according to the embodiment is similar to the pixel arrangement of the image sensor 100 according to the embodiment described with reference to FIG. 2.

The image sensor 102 according to the embodiment may include pixel groups PG, photodiodes PD, color filters CF, micro lenses MLZ, and other circuits required for operation of the image sensor 100.

The plurality of pixels PX may be grouped in a plurality of columns and a plurality of rows to form one unit pixel group PG.

The pixel group PG overlapping a first color filter CF1 may detect light of a first color, the pixel group PG overlapping a second color filter CF2 may detect light of a second color different from the first color, and the pixel group PG overlapping a third color filter CF3 may detect light of a third color different from the first and second colors.

Each of the plurality of pixel groups PG may include N×M pixels PX in an N×M arrangement. The N and the M may each independently be an integer greater than 1. For example, each of N and M may be 4, and may have a 4×4 tetra structure pixel arrangement in a plan view. For example, each of the plurality of pixel groups PG may include pixels PX arranged in a 4×4 shape in a plan view.

More specifically, the plurality of pixels PX disposed in the arrangement direction of the column line CL and the plurality of pixels PX disposed in the arrangement direction of the row line RL may configure one unit pixel group PG. For example, one unit pixel group PG may include a plurality of pixels PX arranged in four columns and four rows. However, the embodiment is not limited thereto, and the number of pixels PX included in one pixel group PG may be variously modified.

Micro lenses MLZ may be disposed one per every two adjacent pixels PX. For example, the micro lenses MLZ may be disposed one per every two adjacent pixels PX in a first direction DR1.

The image sensor 102 according to the embodiment includes a first pixel row in which pixel groups PG corresponding to a first color filter CF1 and a second color filter CF2 are alternately arranged in the first direction DR1, and a second pixel row in which pixel groups PG corresponding to the second color filter CF2 and a third color filter CF3 are alternately arranged in the first direction DR1. The first pixel row and the second pixel row may be alternately arranged in a second direction DR2.

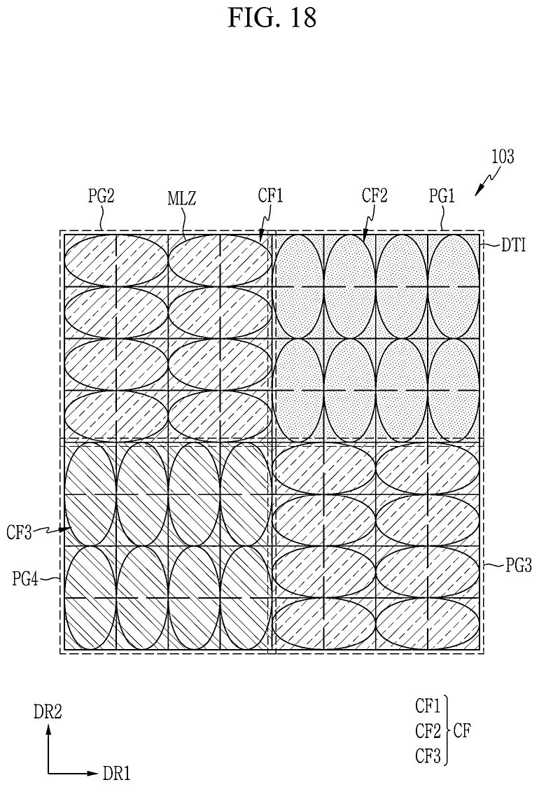

Then, referring to FIG. 18, a pixel arrangement of an image sensor 103 according to an example embodiment will be described. FIG. 18 is a top plan view illustrating a part of an image sensor according to an example embodiment.

Referring to FIG. 18, the pixel arrangement of an image sensor 103 according to the embodiment is similar to the pixel arrangement of the image sensor 101 according to the embodiment described with reference to FIG. 14.

The image sensor 103 according to the embodiment may include pixel groups PG, photodiodes PD, color filters CF, micro lenses MLZ, and other circuits required for operation of the image sensor 103.

The plurality of pixels PX may be grouped in a plurality of columns and a plurality of rows to form one unit pixel group PG.

The pixel group PG overlapping a first color filter CF1 may detect light of a first color, the pixel group PG overlapping a second color filter CF2 may detect light of a second color different from the first color, and the pixel group PG overlapping a third color filter CF3 may detect light of a third color different from the first and second colors.

Each of the plurality of pixel groups PG may include N×M pixels PX in an N×M arrangement. The N and the M may each independently be an integer greater than 1. For example, each of N and M may be 4, and may have a 4×4 tetra structure pixel arrangement in a plan view. For example, each of the plurality of pixel groups PG may include pixels PX arranged in a 4×4 shape in a plan view.

More specifically, the plurality of pixels PX disposed in the arrangement direction of the column line CL and the plurality of pixels PX disposed in the arrangement direction of the row line RL may configure one unit pixel group PG. For example, one unit pixel group PG may include a plurality of pixels PX arranged in four columns and four rows. However, the embodiment is not limited thereto, and the number of pixels PX included in one pixel group PG may be variously modified.

The image sensor 103 according to the embodiment may include a first pixel row in which a first pixel group PG1 corresponding to the first color filter CF1 and a second pixel group PG2 corresponding to the second color filter CF2 are alternately arranged in the first direction DR1, and a second pixel row in which a third pixel group PG3 corresponding to the second color filter CF2 and a fourth pixel group PG4 corresponding to the third color filter CF3 are alternately arranged in the first direction DR1.

Micro lenses MLZ may be disposed one per every two adjacent pixels PX. For example, one micro lens MLZ may be disposed for every two adjacent pixels PX along the first direction DR1, or one micro lens MLZ may be disposed for each two adjacent pixels PX along the second direction DR2.

The first pixel group PG1 may include micro lenses MLZ shared by two adjacent pixels along the second direction DR2, the second pixel group PG2 and the third pixel group PG3 may include micro lenses MLZ shared by two adjacent pixels along the first direction DR1, and the fourth pixel group PG4 may include micro lenses MLZ shared by two adjacent pixels along the second direction DR2.

The first pixel row and the second pixel row may be alternately arranged in a second direction DR2.

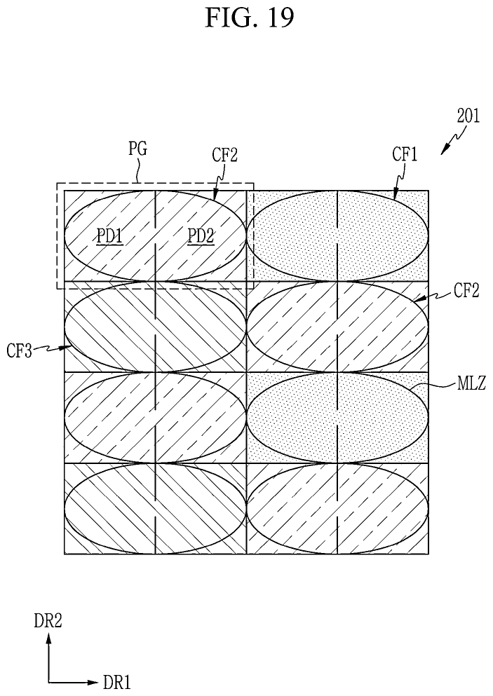

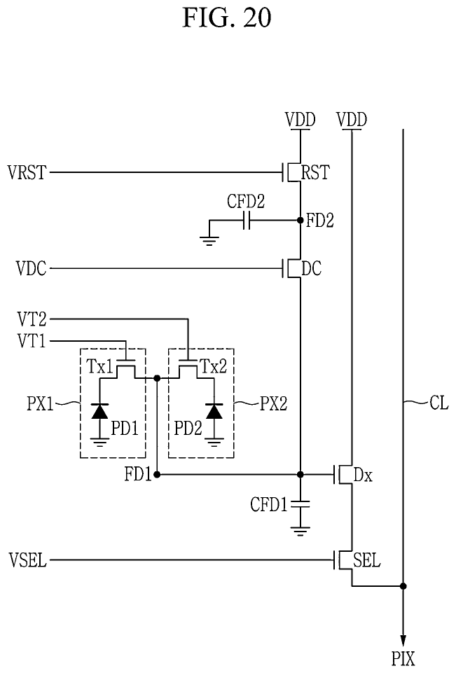

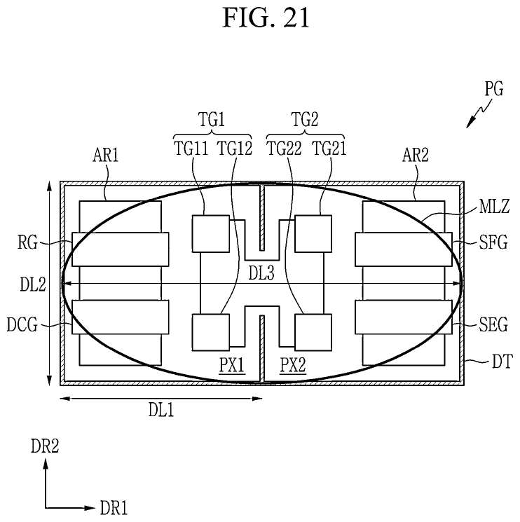

Then, with reference to FIGS. 19 to 21, an image sensor 201 according to another example embodiment will be described. FIG. 19 is a top plan view illustrating a part of an image sensor according to an example embodiment, FIG. 20 is a circuit diagram of a pixel group of an image sensor according to an example embodiment, and FIG. 21 is an enlarged view of a part of FIG. 20.

Referring to FIG. 19, the image sensor 201 according to the embodiment may include pixel groups PG, photodiodes PD, color filters CF, micro lenses MLZ, and other circuits required for operation of the image sensor 100.

The plurality of pixels PX may be grouped in a plurality of columns and a plurality of rows to form one unit pixel group PG.

The pixel group PG overlapping a first color filter CF1 may detect light of a first color, the pixel group PG overlapping a second color filter CF2 may detect light of a second color different from the first color, and the pixel group PG overlapping a third color filter CF3 may detect light of a third color different from the first and second colors.

Each of the plurality of pixel groups PG may include N×M pixels PX in an N×M arrangement. The N and the M may each independently be an integer equal to or greater than 1. For example, the N and M may respectively be 2 and 1, and may have a 2×1 pixel array structure in a plan view. For example, each of the plurality of pixel groups PG may include pixels PX arranged in a 2×1 shape in a plan view.

More specifically, the plurality of pixels PX disposed in the arrangement direction of the column line CL and the plurality of pixels PX disposed in the arrangement direction of the row line RL may configure one unit pixel group PG. For example, one unit pixel group PG may include a plurality of pixels PX arranged in two columns and one row. However, the embodiment is not limited thereto, and the number of pixels PX included in one pixel group PG may be variously modified.

Micro lenses MLZ may be disposed one per every two adjacent pixels PX. For example, the micro lenses MLZ may be disposed one per every two adjacent pixels PX in a first direction DR1.

The image sensor 201 according to the embodiment includes a first pixel row in which pixel groups PG corresponding to a first color filter CF1 and a second color filter CF2 are alternately arranged in the first direction DR1, and a second pixel row in which pixel groups PG corresponding to the second color filter CF2 and a third color filter CF3 are alternately arranged in the first direction DR1. The first pixel row and the second pixel row may be alternately arranged in a second direction DR2.

Referring to FIG. 20, one pixel group PG of the image sensor 201 according to the embodiment may include pixels PX1 and PX2, photoelectric conversion elements PD1 and PD2, transfer transistors Tx1 to Tx2, a reset transistor RST, a dual conversion transistor DC, a driving transistor Dx, and a selection transistor SEL. As described above, the pixel group PG is shown as having two pixels PX1 and PX2 each including photoelectric conversion elements PD1 and PD2, but the present disclosure is not limited thereto, and the pixel group PG may be implemented to have various other structures.

The first pixel PX1 may include the first photoelectric conversion element PD1 and the first transfer transistor Tx1, and the second pixel PX2 may include the second photoelectric conversion element PD2 and the second transfer transistor Tx2.

The pixels PX1 and PX2 of one pixel group PG may share a reset transistor RST, a dual conversion transistor DC, a driving transistor Dx, and a selection transistor SEL. Additionally, each of the pixels PX1 and PX2 may share the first floating diffusion region FD1.

The first floating diffusion region FD1 or a second floating diffusion region FD2 may accumulate charges corresponding to the amount of incident light.

While the transfer transistors Tx1 and Tx2 are each turned on by the transfer signals VT1 and VT2, the first floating diffusion region FD1 or the second floating diffusion region FD2 may receive and accumulate charges from the photoelectric conversion elements PD1 to PD2.

Since the first floating diffusion region FD1 may be connected to the gate terminal of the driving transistor Dx driven as a source follower amplifier, a voltage corresponding to the charges accumulated in the first floating diffusion region FD1 may be formed. For example, the capacitance of the first floating diffusion region FD1 may be represented as a first capacitance CFD1.

The dual conversion transistor DC may be driven by a dual conversion signal VDC. When the dual conversion transistor DC is turned off, the capacitance of the first floating diffusion region FD1 may correspond to the first capacitance CFD1.

In a general environment, the first floating diffusion region FD1 is not easily saturated, so the need to increase the capacitance of the first capacitance CFD1 of the first floating diffusion region FD1 may not be required, and the dual conversion transistor DC may be turned off.

However, in a high-light environment, the first floating diffusion region FD1 may easily become saturated. To prevent such saturation, the dual conversion transistor DC may be turned on, the first floating diffusion region FD1 may be electrically connected to the second floating diffusion region FD2, and the capacitance of the floating diffusion regions FD1 and FD2 may be expanded to the sum of the first capacitance CFD1 and the second capacitance CFD2.

The transfer transistors Tx1 and Tx2 may each be driven by the transfer signals VT1 and VT2, and may transmit charges generated by photoelectric conversion elements PD1 and PD2 to the first floating diffusion region FD1 or the second floating diffusion region FD2. For example, one end of each of the transfer transistors Tx1 and Tx2 may be connected to the photoelectric conversion elements PD1 and PD2, respectively, and the other end of each of the transfer transistor Tx1 and Tx2 may be connected to the first floating diffusion region FD1.

The reset transistor RST may be driven by the reset signal VRST and may provide a power supply voltage VDD to the first floating diffusion region FD1 or the second floating diffusion region FD2. Accordingly, the charges accumulated in the first floating diffusion region FD1 or in the expanded second floating diffusion region FD2 may move to the power supply voltage VDD end, and the voltage of the first floating diffusion region FD1 or the second floating diffusion region FD2 may be reset.

The driving transistor Dx may generate a pixel signal PIX by amplifying the voltage of the first floating diffusion region FD1 or the second floating diffusion region FD2. The selection transistor SEL may be driven by the selection signal VSEL, and may select pixels to be read in row units. When the selection transistor SEL is turned on, the pixel signal PIX may be output to the readout circuit 150 through the column line CL.

Referring to FIG. 21, the image sensor 201 according to the embodiment may include a pixel group PG including the plurality of pixels PX1 and PX2 adjacent to each other. For example, the plurality of pixels PX1 and PX2 may include the first pixel PX1 and the second pixel PX2 adjacent to each other along the first direction DR1.

One micro lens MLZ may be disposed on the first pixel PX1 and the second pixel PX2 adjacent to each other along the first direction DR1.

Each of the first pixel PX1 and the second pixel PX2 may have the first length DL1 along the first direction DR1, and the second length DL2 along the second direction DR2. The first length DL1 and the second length DL2 may be substantially the same, and the ratio of the second length DL2 to the first length DL1 may be about 0.9 to about 1.1.

The micro lens MLZ shared by the first pixel PX1 and the second pixel PX2 may have the third length DL3 along the direction DR1 and the second length DL2 along the second direction DR2. The third length DL3 may be about twice the second length DL2, and the ratio of the third length DL3 to the second length DL2 may be about 1.8 to about 2.2.

The plurality of pixels PX1 and PX2 may be distinguished by the pixel isolation structure DTI. The pixel isolation structure DTI may be connected to each other and disposed to surround the first pixel PX1 and the second pixel PX2. The pixel isolation structure DTI may prevent crosstalk between the plurality of pixels PX1 and PX2. The pixel isolation structure DTI may be disposed in the deep trench DT.

The pixel isolation structure DTI may not be disposed in a part of the region between the first pixel PX1 and the second pixel PX2 that are adjacent to each other and share the micro lens MLZ.

The pixel isolation structure DTI may include the first portion DTI1 disposed on the outer portion to surround the first pixel PX1 and the second pixel PX2, and the fourth portion DTI4 connected to the first portion DTI1 and extending parallel to the second direction DR2 and disposed between the first pixel PX1 and the second pixel PX2.

The fourth portion DTI4 may not be disposed in the center between the first pixel PX1 and the second pixel PX2 of the plurality of pixels PX1 and PX2. For example, the pixel isolation structure DTI may not be disposed in the center region between the first pixel PX1 and the second pixel PX2 that are adjacent to each other and share the micro lens MLZ. The region between the first pixel PX1 and the second pixel PX2 where the pixel isolation structure DTI is not disposed may overlap with the center portion of the micro lens MLZ.

The plurality of pixels PX1 and PX2 may include a plurality of gates TG1, TG2, SFG, SEG, RG, and DCG. The plurality of gates TG1, TG2, SFG, SEG, RG, and DCG may include the transfer gates TG1 and TG2, the drive gate SFG, the selection gate SEG, the reset gate RG, and the dual conversion gate DCG.

The transfer gates TG1 and TG2 may include the first transfer gate TG1 disposed at the first pixel PX1 and the second transfer gate TG2 disposed at the second pixel PX2.

The first transfer gate TG1 may include two transfer gates TG11 and TG12, and the second transfer gate TG2 may include two transfer gates TG21 and TG22.

The two transfer gates TG11 and TG12 disposed at the first pixel PX1 may be the gate electrodes of the first transfer transistor Tx1, and the two transfer gates TG21 and TG22 disposed at the second pixel PX2 may be the gate electrodes of the second transfer transistor Tx2.

The first transfer gate TG1 and the second transfer gate TG2 may overlap the first floating diffusion region FD1.

The first floating diffusion region FD1 disposed at the first pixel PX1 and the second pixel PX2 may be directly connected through the region between the first pixel PX1 and the second pixel PX2 without being separated by the pixel isolation structure DTI.

The first floating diffusion region FD1 between the first pixel PX1 and the second pixel PX2 may overlap the center portion of the micro lens MLZ along the optical axis direction.

As described above, the pixels PX1 and PX2 of one pixel group PG may share a reset transistor RST, a dual conversion transistor DC, a driving transistor Dx, and a selection transistor SEL.

The reset gate RG disposed at the first pixel PX1 may form the reset transistor RST with the first active region AR1, and the dual conversion gate DCG disposed at the first pixel PX1 may form the dual conversion transistor DC with the first active area AR1.

The drive gate SFG disposed at the second pixel PX2 may form the drive transistor Dx with the second active region AR2, and the selection gate SEG disposed at the second pixel PX2 may form the selection transistor SEL with the second active region AR2.

The positions of the reset gate RG, drive gate SFG, dual conversion gate DCG, and selection gate SEG are not limited thereto, and the positions of the reset gate RG, drive gate SFG, dual conversion gate DCG, and selection gate SEG may be changed in various ways so that the plurality of pixels PX1, PX2, PX3, and PX4 may share the reset gate RG, drive gate SFG, dual conversion gate DCG, and selection gate SEG.

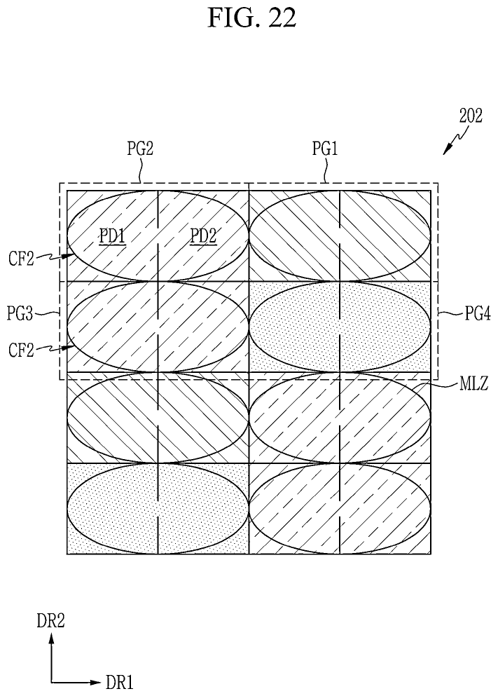

With reference to FIG. 22, pixel arrangement of the image sensor 202 according to another example embodiment will be described. FIG. 22 is a top plan view illustrating a part of an image sensor according to another example embodiment.

Referring to FIG. 22, the pixel arrangement of an image sensor 202 according to the embodiment is similar to the pixel arrangement of the image sensor 201 according to the embodiment described with reference to FIG. 17.

The image sensor 202 according to the embodiment may include pixel groups PG, photodiodes PD, color filters CF, micro lenses MLZ, and other circuits required for operation of the image sensor 202.

The pixel group PG overlapping a first color filter CF1 may detect light of a first color, the pixel group PG overlapping a second color filter CF2 may detect light of a second color different from the first color, and the pixel group PG overlapping a third color filter CF3 may detect light of a third color different from the first and second colors.

Each of the plurality of pixel groups PG may include N×M pixels PX in an N×M arrangement. The N and the M may each independently be an integer equal to or greater than 1. For example, the N and M may respectively be 2 and 1, and may have a 2×1 pixel array structure in a plan view. For example, each of the plurality of pixel groups PG may include pixels PX arranged in a 2×1 shape in a plan view.

More specifically, the plurality of pixels PX disposed in the arrangement direction of the column line CL and the plurality of pixels PX disposed in the arrangement direction of the row line RL may configure one unit pixel group PG. For example, one unit pixel group PG may include a plurality of pixels PX arranged in two columns and one row. However, the embodiment is not limited thereto, and the number of pixels PX included in one pixel group PG may be variously modified.

The image sensor 202 according to the embodiment may include a first pixel row in which a first pixel group PG1 corresponding to the first color filter CF1 and a second pixel group PG2 corresponding to the second color filter CF2 are alternately arranged in the first direction DR1, and a second pixel row in which a third pixel group PG3 corresponding to the second color filter CF2 and a fourth pixel group PG4 corresponding to the third color filter CF3 are alternately arranged in the first direction DR1.

Micro lenses MLZ may be disposed one per every two adjacent pixels PX. For example, one micro lens MLZ may be disposed for every two adjacent pixels PX along the first direction DR1.

Each pixel group PG1, PG2, PG3, and PG4 may include micro lenses MLZ shared by two adjacent pixels along the first direction DR1.

The first pixel row and the second pixel row may be alternately arranged in a second direction DR2.

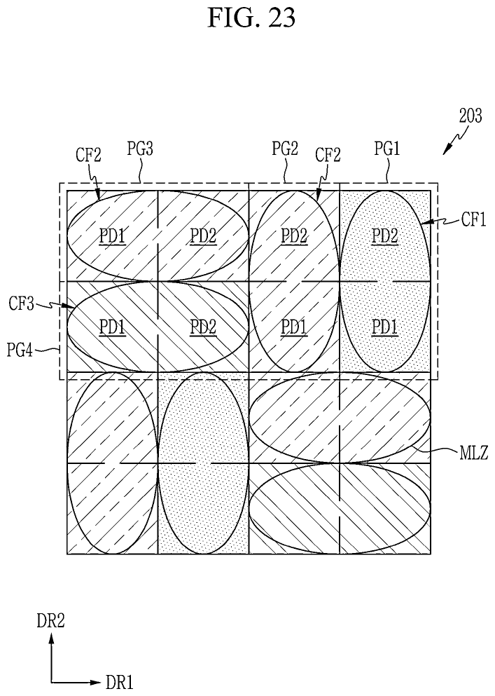

With reference to FIG. 23, pixel arrangement of an image sensor 203 according to another example embodiment will be described. FIG. 23 is a top plan view illustrating a part of an image sensor according to another example embodiment.

Referring to FIG. 23, the pixel arrangement of the image sensor 203 according to the embodiment is similar to the pixel arrangement of the image sensors 201 and 202 according to the embodiments described above.

The image sensor 203 according to the embodiment may include pixel groups PG, photodiodes PD, color filters CF, micro lenses MLZ, and other circuits required for operation of the image sensor 203.

The pixel group PG overlapping a first color filter CF1 may detect light of a first color, the pixel group PG overlapping a second color filter CF2 may detect light of a second color different from the first color, and the pixel group PG overlapping a third color filter CF3 may detect light of a third color different from the first and second colors.

Each of the plurality of pixel groups PG may include N×M pixels PX in an N×M arrangement. The N and the M may each independently be an integer equal to or greater than 1. For example, the N and the M may have a 2×1 pixel array structure in a plan view as 2 and 1, or the N and the M may have a 1×2 pixel array structure in a plan view as 1 and 2.

For example, each of the plurality of pixel groups PG may include pixels PXs arranged in a 2×1 shape or pixels PXs arranged in a 1×2 shape in a plan view. However, the embodiment is not limited thereto, and the number of pixels PX included in one pixel group PG may be variously modified.

The image sensor 203 according to the embodiment may include the first pixel group PG1 including two adjacent pixels along the second direction DR2 and corresponding to the first color filter CF1, the second pixel group PG2 including two adjacent pixels along the second direction DR2, adjacent to the first pixel group PG1, and corresponding to the second color filter CF2, the third pixel group PG3 including two adjacent pixels along the first direction DR1 and corresponding to the second color filter CF2, and the fourth pixel group PG4 including two adjacent pixels along the first direction DR1, adjacent to the third pixel group PG3, and corresponding to the third color filter CF3.

The first pixel group PG1 and the second pixel group PG2, and the third pixel group PG3 and the fourth pixel group PG4 may be alternately arranged in pairs along the first direction DR1 and the second direction DR2.

The first pixel group PG1 and the second pixel group PG2 may each include a micro lens MLZ disposed at every two adjacent pixels along the second direction DR2, and the third pixel group PG3 and the fourth pixel group PG4 may each include a micro lens MLZ disposed every two pixels along the first direction DR1.

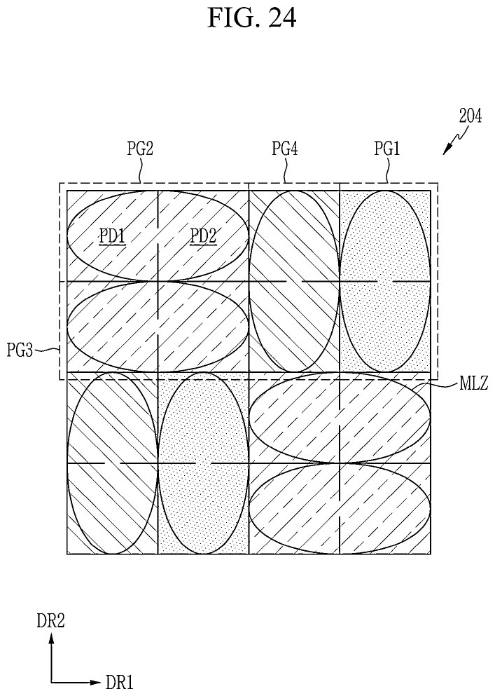

With reference to FIG. 24, pixel arrangement of an image sensor 204 according to another example embodiment will be described. FIG. 24 is a top plan view illustrating a part of an image sensor according to another example embodiment.

Referring to FIG. 24, the pixel arrangement of the image sensor 204 according to the embodiment is similar to the pixel arrangement of the image sensors 201, 202, and 203 according to the embodiments described above.

The image sensor 204 according to the embodiment may include pixel groups PG, photodiodes PD, color filters CF, micro lenses MLZ, and other circuits required for operation of the image sensor 204.

The pixel group PG overlapping a first color filter CF1 may detect light of a first color, the pixel group PG overlapping a second color filter CF2 may detect light of a second color different from the first color, and the pixel group PG overlapping a third color filter CF3 may detect light of a third color different from the first and second colors.

Each of the plurality of pixel groups PG may include N×M pixels PX in an N×M arrangement. The N and the M may each independently be an integer equal to or greater than 1. For example, the N and the M may have a 2×1 pixel array structure in a plan view as 2 and 1, or the N and the M may have a 1×2 pixel array structure in a plan view as 1 and 2. For example, each of the plurality of pixel groups PG may include pixels PXs arranged in a 2×1 shape or pixels PXs arranged in a 1×2 shape in a plan view. However, the embodiment is not limited thereto, and the number of pixels PX included in one pixel group PG may be variously modified.

The image sensor 204 according to the embodiment may include the first pixel group PG1 including two adjacent pixels along the second direction DR2 and corresponding to the first color filter CF1, the second pixel group PG2 including two adjacent pixels along the first direction DR1 and corresponding to the second color filter CF2, the third pixel group PG3 adjacent to the second pixel group PG2, including two adjacent pixels along the first direction DR1, and corresponding to the second color filter CF2, and the fourth pixel group PG4 including two adjacent pixels along the second direction DR2, adjacent to the first pixel group PG1, and corresponding to the third color filter CF3.

The first pixel group PG1 and the fourth pixel group PG4, and the second pixel group PG2 and the third pixel group PG3 and may be alternately arranged in pairs along the first direction DR1 and the second direction DR2.

The first pixel group PG1 and the fourth pixel group PG4 may each include a micro lens MLZ disposed at every two adjacent pixels along the second direction DR2, and the second pixel group PG2 and the third pixel group PG3 may each include a micro lens MLZ disposed every two pixels along the first direction DR1.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

### DESCRIPTION OF SYMBOLS

100, 101, 102, 103, 201, 202, 203, 204: Image sensor
200: Substrate
AR1, AR2, AR3, AR4: Active region
CF: Color filter
DTI: Pixel isolation structure
FD1, FD2: Floating diffusion region
HDT: Half-pixel isolation structure
MLZ, MLZ1, MLZ2: Micro lens
PD1, PD2, PD3, PD4: Photoelectric conversion region
PG, PG1, PG2, PG3, PG4, PG5, PG6: Pixel group
PX, PX1, PX2, PX3, PX4: Pixel
TG1, TG2, TG3, TG4: Transfer gate
Tx1, Tx2, Tx3, Tx4: Transfer transistor
RG: Reset gate
RST: Reset transistor
SEG: Selection gate
SEL: Selection transistor
SFG: Drive gate
Dx: Drive transistor

What is claimed is:

1. An image sensor, comprising:
a first pixel and a second pixel adjacent to each other along a first direction;
a first micro lens disposed on the first pixel and the second pixel;
a first pixel isolation structure disposed outside the first pixel and the second pixel and penetrating from a first surface of a substrate to a second surface of the substrate opposite the first surface of the substrate;
a first floating diffusion region disposed at the first pixel and the second pixel and adjacent to the first surface of the substrate;
a first transfer gate disposed at the first pixel and adjacent to the first floating diffusion region;
a second transfer gate disposed at the second pixel and adjacent to the first floating diffusion region;
a first active region disposed at the first pixel and adjacent to the first surface of the substrate;
a first gate disposed at the first pixel and overlapping the first active region;
a second active region disposed at the second pixel and adjacent to the first surface of the substrate; and
a second gate disposed at the second pixel and overlapping the second active region,
wherein the first floating diffusion region does not overlap the first pixel isolation structure along a height direction perpendicular to the first and second surfaces of the substrate, and
wherein the first floating diffusion region between the first pixel and the second pixel is disposed at a position corresponding to a center portion of the first micro lens along an optical axis direction.

2. The image sensor of claim 1, further comprising:
a third pixel adjacent to the first pixel along a second direction different from the first direction and a fourth pixel adjacent to the second pixel along the second direction;
a second micro lens disposed on the third pixel and the fourth pixel; and
a second floating diffusion region disposed at the third pixel and the fourth pixel and adjacent to the first surface of the substrate,
wherein the first pixel isolation structure extends to an outside of the third pixel and the fourth pixel,
wherein the second floating diffusion region does not overlap the first pixel isolation structure along the height direction, and
wherein the second floating diffusion region between the third pixel and the fourth pixel is disposed at a position corresponding to a center portion of the second micro lens along the optical axis direction.

3. The image sensor of claim 2, further comprising:
a third transfer gate disposed at the third pixel and adjacent to the second floating diffusion region;
a fourth transfer gate disposed at the fourth pixel and adjacent to the second floating diffusion region;
a third active region disposed at the third pixel and adjacent to the first surface of the substrate;
a third gate disposed at the third pixel and overlapping the third active region;
a fourth active region disposed at the fourth pixel and adjacent to the first surface of the substrate; and
a fourth gate disposed at the fourth pixel and overlapping the fourth active region.

4. The image sensor of claim 3, further comprising:
a second pixel isolation structure connected to the first pixel isolation structure, extending parallel to the first direction, and disposed between the first pixel and the third pixel and between the second pixel and the fourth pixel.

5. The image sensor of claim 4, wherein:
the first gate is a reset gate, the second gate is a drive gate, the third gate is a dual conversion gate, and the fourth gate is a selection gate,
the first active region and the first gate form a reset transistor,
the second active region and the second gate form a driving transistor,
the third active region and the third gate form a dual conversion transistor, and
the fourth active region and the fourth gate form a selection transistor.

6. The image sensor of claim 5, further comprising:
a third floating diffusion region connected between the reset transistor and the dual conversion transistor.

7. The image sensor of claim 3, wherein:
the first active region and the third active region are connected to each other on the first surface of the substrate, and
the second active region and the fourth active region are connected to each other on the first surface of the substrate.

8. The image sensor of claim 7, further comprising:
a half-pixel isolation structure connected to the first pixel isolation structure, extending parallel to the first direction, disposed between the first pixel and the third pixel and between the second pixel and the fourth pixel, and disposed on a part of the substrate from the second surface of the substrate along the height direction.

9. The image sensor of claim 8, further comprising:
a first photoelectric conversion element disposed at the first pixel, a second photoelectric conversion element disposed at the second pixel, a third photoelectric conversion element disposed at the third pixel, and a fourth photoelectric conversion element disposed at the fourth pixel in the substrate,
wherein the half-pixel isolation structure is disposed between the first photoelectric conversion element and the third photoelectric conversion element and between the second photoelectric conversion element and the fourth photoelectric conversion element.

10. The image sensor of claim 9, wherein:
the first gate is a reset gate, the second gate is a drive gate, the third gate is a dual conversion gate, and the fourth gate is a selection gate,
the first active region and the first gate form a reset transistor,
the second active region and the second gate form a driving transistor,
the third active region and the third gate form a dual conversion transistor, and
the fourth active region and the fourth gate form a selection transistor.

11. The image sensor of claim 10, further comprising:
a third floating diffusion region connected between the reset transistor and the dual conversion transistor.

12. The image sensor of claim 8, further comprising:
a fourth floating diffusion region disposed adjacent to the first surface of the substrate, and connected between the first floating diffusion region and the second floating diffusion region.

13. The image sensor of claim 12, wherein:
the fourth floating diffusion region overlaps the half-pixel isolation structure along the height direction.

14. The image sensor of claim 13, wherein:
the first gate is a reset gate, the second gate is a drive gate, the third gate is a dual conversion gate, and the fourth gate is a selection gate,
the first active region and the first gate form a reset transistor,
the second active region and the second gate form a driving transistor,
the third active region and the third gate form a dual conversion transistor, and
the fourth active region and the fourth gate form a selection transistor.

15. The image sensor of claim 14, further comprising:
a third floating diffusion region connected between the reset transistor and the dual conversion transistor.

16. The image sensor of claim 12, wherein the fourth floating diffusion region does not overlap the half-pixel isolation structure along the height direction.

17. The image sensor of claim 16, wherein:
the first gate is a reset gate, the second gate is a drive gate, the third gate is a dual conversion gate, and the fourth gate is a selection gate,
the first active region and the first gate form a reset transistor,
the second active region and the second gate form a driving transistor,
the third active region and the third gate form a dual conversion transistor, and
the fourth active region and the fourth gate form a selection transistor.

18. The image sensor of claim 17, further comprising:
a third floating diffusion region connected between the reset transistor and the dual conversion transistor.

19. The image sensor of claim 1, further comprising:
a third gate disposed at the first pixel and overlapping the first active region; and
a fourth gate disposed at the first pixel and overlapping the second active region.

20. The image sensor of claim 19, wherein:
the first gate is a reset gate, the second gate is a drive gate, the third gate is a dual conversion gate, and the fourth gate is a selection gate,
the first active region and the first gate form a reset transistor,
the second active region and the second gate form a driving transistor,
the first active region and the third gate form a dual conversion transistor, and
the second active region and the fourth gate form a selection transistor.
